(19) United States
(12) Patent Application Publication
(10) Pub. No.: US 2019/0028073 A1
(43) Pub. Date: Jan. 24, 2019

(54) ELECTRONIC DEVICE AND WIRELESS COMMUNICATION METHOD OF ELECTRONIC DEVICE

(71) Applicant: Samsung Electronics Co., Ltd., Gyeonggi-do (KR)

(72) Inventors: Jae-Gon GHIM, Gyeonggi-do (KR); Nam-Woo KIM, Gyeonggi-do (KR); Dong-Han KIM, Gyeonggi-do (KR); Tae-Il KIM, Yongin-si (KR)

(21) Appl. No.: 16/036,137

(22) Filed: Jul. 16, 2018

(30) Foreign Application Priority Data
Jul. 18, 2017 (KR) 10-2017-0091099

(51) Int. Cl. H03F 3/24; H04W 72/04

(52) U.S. Cl. CPC H03F 3/24; H04W 4/70; H04W 72/0453

(57) ABSTRACT

Disclosed is an electronic device including: a communication circuit; and a processor operationally connected to the communication circuit, where the processor is configured to use the communication circuit to merge a first transmission signal of a first communication scheme corresponding to a first band that is one of transmission bands of the first communication scheme and a second transmission signal of a second communication scheme corresponding to a second band that is one of the transmission bands, amplify the merged first transmission signal and second transmission signal using a power amplifier, transmit the amplified first transmission signal to a first external electronic device communicating in the first communication scheme, and transmit the amplified second transmission signal to a second external electronic device communicating in the second communication scheme. Other various embodiments are possible.

### CROSS-REFERENCE TO RELATED APPLICATION

This application claims the priority under 35 U.S.C. § 119(a) to Korean Patent Application Serial No. 10-2017-0091099, which was filed in the Korean Intellectual Property Office on Jul. 18, 2017, the entire content of which is hereby incorporated by reference.

### TECHNICAL FIELD

The present disclosure generally relates to wireless communication and more particularly to an electronic device and a wireless communication method of the electronic device capable of providing a cellular communication network and Device-to-Device (D2D) communication.

### BACKGROUND

Recently, due to the development of various wireless communication methods, various types of communication such as wireless communication through a communication network or Device-to-Device (D2D) communication can be performed by an electronic device such as a smart device.

The above-mentioned wireless communication through the communication network may include communication using a cellular communication network scheme, and the electronic device can communicate with another electronic device through a Base Station (BS) and an Evolved Packet Core (EPC) network in, for example, a cellular communication network such as a Long-Term Evolution (LTE) or LTE-Advanced (LTE-A) communication network. For example, the electronic device may transmit a data packet to a serving BS through an uplink band, which is one of various communication bands of the cellular communication network scheme. In addition, the electronic device may receive a data packet from the serving BS through a downlink band.

The above-mentioned D2D communication may be communication based on cellular communication (hereinafter, referred to as “cellular-based D2D communication”), and electronic devices adjacent to each other can perform the D2D communication using cellular-based D2D communication technology such as Proximity based services (ProSe) therebetween.

The wireless communication circuit of the conventional electronic device may perform both the communication through the cellular communication network and the cellular-based D2D communication using a half duplexing scheme that employs the uplink band of the cellular communication network.

The above information is presented as background information only to assist with an understanding of the disclosure. No determination has been made, and no assertion is made, as to whether any of the above might be applicable as prior art with regard to the disclosure.

### SUMMARY

When cellular-based D2D communication should be performed between a cellular communication network and electronic devices, the electronic devices may support the cellular-based D2D communication using uplink bands of the cellular communication network. As mentioned above, the electronic devices may use a half duplexing scheme to support the cellular-based D2D communication. However, wireless communication circuits of the electronic devices supporting cellular-based D2D communication, which uses the uplink bands of the cellular communication network, generally cannot simultaneously perform the cellular communication networking and the cellular-based D2D communication.

According to various embodiments, an electronic device and a wireless communication method of the electronic device capable of simultaneously performing the cellular communication networking and the cellular-based D2D communication are provided.

In accordance with an aspect of the present disclosure, an electronic device is provided. The electronic device includes: a communication circuit; and a processor operationally connected to the communication circuit, where the processor is configured to use the communication circuit to merge a first transmission signal of a first communication scheme corresponding to a first band that is one of transmission bands of the first communication scheme and a second transmission signal of a second communication scheme corresponding to a second band that is one of the transmission bands, amplify the merged first transmission signal and second transmission signal using a power amplifier, transmit the amplified first transmission signal to a first external electronic device communicating in the first communication scheme, and transmit the amplified second transmission signal to a second external electronic device communicating in the second communication scheme.

In accordance with another aspect of the present disclosure, a wireless communication method of an electronic device is provided. The wireless communication method includes: merging a first transmission signal of a first communication scheme corresponding to a first band that is one of transmission bands of the first communication scheme and a second transmission signal of a second communication scheme corresponding to a second band that is one of the transmission bands; amplifying the merged first transmission signal and second transmission signal using a power amplifier; transmitting the amplified first transmission signal to a first external electronic device communicating in the first communication scheme; and transmitting the amplified second transmission signal to a second external electronic device communicating in the second communication scheme.

In accordance with another aspect of the present disclosure, a computer-readable recording medium having a program recorded therein to be performed on a computer is provided. The program includes executable instructions that, when executed by a processor, cause the processor to perform operations through a communication circuit operationally connected to the processor. The operations includes: merging a first transmission signal of a first communication scheme corresponding to a first band that is one of transmission bands of the first communication scheme and a second transmission signal of a second communication scheme corresponding to a second band that is one of the transmission bands; amplifying the merged first transmission signal and second transmission signal using a power amplifier; transmitting the amplified first transmission signal to a first external electronic device communicating in the first communication scheme; and transmitting the amplified second transmission signal to a second external electronic device communicating in the second communication scheme.

In accordance with another aspect of the present disclosure, an electronic device is provided. The electronic device includes: a housing; an antenna unit at least partially disposed inside or on the housing; at least one transceiver circuit including a first port, a second port, a third port, and a fourth port; a first merger including a first input terminal electrically connected to the first port, a second input terminal electrically connected to the second port, and an output terminal; a power amplifier including an input terminal electrically connected to the output terminal of the first merger and an output terminal; and a switching unit including a first terminal electrically connected to the output terminal of the power amplifier, a second terminal electrically connected to the third port, and a third terminal electrically connected to the antenna unit, where the fourth port is electrically connected to the antenna unit without being electrically connected to the first merger, the power amplifier, and the switching unit. Further, the transceiver circuit is configured transmit Long-Term Evolution (LTE) UpLink (UL) transmission data corresponding to a first band that is one of LTE UL bands through the first port, transmit LTE Device-to-Device (D2D) transmission data corresponding to a second band that is one of the LTE UL bands through the second port, receive LTE D2D reception data corresponding to the second band through the third port, and receive LTE DownLink (DL) reception data corresponding to LTE DL bands through the fourth port.

According to various embodiments, it is possible to simultaneously perform the cellular communication networking and the cellular-based D2D communication by merging, amplifying, and transmitting signals corresponding to the cellular communication network and the cellular-based D2D communication.

According to various embodiments, it is possible to minimize the mounting space or cost by providing a wireless communication circuit for merging and transmitting signals corresponding to the cellular communication network and the cellular-based D2D communication.

According to various embodiments, it is possible to reduce resources required for operating the wireless communication circuit, such as power consumption, by controlling a voltage for driving the wireless communication circuit in order to amplify and transmit the merged signals.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 illustrates an electronic device within a network environment according to an embodiment;

FIG. 2 is a block diagram of the electronic device according to an embodiment;

FIG. 3 is a block diagram of a program module according to an embodiment;

FIG. 4 illustrates a wireless communication scheme of the electronic device according to an embodiment;

FIG. 5 is a block diagram of the electronic device according to an embodiment;

FIG. 6A, FIG. 6B, FIG. 6C, FIG. 6D and FIG. 6E are block diagrams illustrating a communication circuit of the electronic device according to various embodiments;

FIG. 7A illustrates an example of a first baseband transmission signal of a first communication scheme according to an embodiment;

FIG. 7B illustrates an example of a second baseband transmission signal of a second communication scheme according to an embodiment;

FIG. 8A illustrates an example of the first transmission signal of the first communication scheme corresponding to a first band that is one of the transmission bands of the first communication scheme of the electronic device, according to an embodiment;

FIG. 8B illustrates an example of the second transmission signal of the second communication scheme corresponding to a second band that is one of the transmission bands of the first communication scheme of the electronic device, according to an embodiment;

FIG. 9A illustrates an example of a first adaptive voltage corresponding to the first transmission signal of the first communication scheme, which in turn corresponds to a first band that is one of the transmission bands of the first communication scheme of the electronic device, according to an embodiment;

FIG. 9B illustrates an example of a second adaptive voltage corresponding to the second transmission signal of the second communication scheme, which in turn corresponds to a second band that is one of the transmission bands of the first communication scheme of the electronic device, according to an embodiment;

FIG. 10A illustrates an example of a baseband transmission signal obtained by merging the first baseband transmission signal of the second communication scheme, which in turn corresponds to a second band that is one of the transmission bands of the first communication scheme of the electronic device, according to an embodiment;

FIG. 10A illustrates an example of a baseband transmission signal obtained by merging the first baseband transmission signal of the first communication scheme and the second baseband transmission signal of the second communication scheme, according to an embodiment;

FIG. 10B illustrates an example of an envelope voltage corresponding to an output voltage of the baseband transmission signal obtained by merging the first baseband transmission signal and the second baseband transmission signal of the electronic device, according to an embodiment;

FIG. 11 is a flowchart illustrating a wireless communication method of the electronic device according to an embodiment;

FIG. 12 is a flowchart illustrating a wireless communication method of the electronic device according to an embodiment;

FIG. 13 is a flowchart illustrating a wireless communication method of the electronic device according to an embodiment;

FIG. 14 is a flowchart illustrating a wireless communication method of the electronic device according to an embodiment;

FIG. 15 is a flowchart illustrating a wireless communication method of the electronic device according to an embodiment;

FIG. 16 is a flowchart illustrating a wireless communication method of the electronic device according to an embodiment; and

FIG. 17 is a flowchart illustrating a wireless communication method of the electronic device according to an embodiment.

### DETAILED DESCRIPTION

Hereinafter, various embodiments will be described with reference to the accompanying drawings. The embodiments and the terms used therein are not intended to limit the technology disclosed herein to specific forms, and should be understood to include various modifications, equivalents, and/or alternatives to the corresponding embodiments. In describing the drawings, similar reference numerals may be used to designate similar constituent elements. As used herein, singular forms may include plural forms as well unless the context clearly indicates otherwise. The expression “a first,” “a second,” “the first,” or “the second” may refer to corresponding components without implying an order of importance, and are used merely to distinguish each component from the others without unduly limiting the components. When an element (e.g., first element) is referred to as being “(operationally or functionally or communicatively) connected,” or “directly coupled” to another element (second element), the element may be connected directly to the another element or connected to the another element through yet another element (e.g., third element).

The expression “configured to” as used in various embodiments may be interchangeably used with, for example, “suitable for,” “having the capacity to,” “designed to,” “adapted to,” “made to,” or “capable of” in terms of hardware or software, depending on the context. Alternatively, in some situations, the expression “device configured to” may mean that the device, together with other devices or components, “is able to.” For example, the phrase “processor adapted (or configured) to perform A, B, and C” may mean a dedicated processor (e.g., embedded processor) only for performing the corresponding operations or a generic-purpose processor (e.g., Central Processing Unit (CPU) or Application Processor (AP)) that can perform the corresponding operations by executing one or more software programs stored in a memory device.

An electronic device according to various embodiments may include at least one of, for example, a smart phone, a tablet Personal Computer (PC), a mobile phone, a video phone, an electronic book reader (e-book reader), a desktop PC, a laptop PC, a netbook computer, a workstation, a server, a Personal Digital Assistant (PDA), a Portable Multimedia Player (PMP), a MPEG-1 audio layer-3 (MP3) player, a mobile medical device, a camera, and a wearable device. According to various embodiments, the wearable device may include at least one of an accessory type (e.g., a watch, a ring, a bracelet, an anklet, a necklace, a glasses, a contact lens, or a Head-Mounted Device (HMD)), a fabric or clothing integrated type (e.g., an electronic clothing), a body-mounted type (e.g., a skin pad, or tattoo), and a bio-implantable type (e.g., an implantable circuit). In some embodiments, the electronic device may include at least one of, for example, a television, a Digital Video Disk (DVD) player, an audio, a refrigerator, an air conditioner, a vacuum cleaner, an oven, a microwave oven, a washing machine, an air cleaner, a set-top box, a home automation control panel, a security control panel, a TV box (e.g., Samsung HomeSync™, Apple TV™, or Google TV™), a game console (e.g., Xbox™ and PlayStation™), an electronic dictionary, an electronic key, a camcorder, and an electronic photo frame.

In other embodiments, the electronic device may include at least one of various medical devices (e.g., various portable medical measuring devices (a blood glucose monitoring device, a heart rate monitoring device, a blood pressure measuring device, a body temperature measuring device, etc.), a Magnetic Resonance Angiography (MRA) device, a Magnetic Resonance Imaging (MRI) device, a Computed Tomography (CT) machine, and an ultrasonic machine), a navigation device, a Global Positioning System (GPS) receiver, an Event Data Recorder (EDR), a Flight Data Recorder (FDR), a Vehicle Infotainment Devices, an electronic devices for a ship (e.g., a navigation device for a ship, and a gyro-compass), avionics, security devices, an automotive head unit, a robot for home or industry, an Automatic Teller's Machine (ATM) in banks, Point Of Sales (POS) in a shop, or internet device of things (e.g., a light bulb, various sensors, electric or gas meter, a sprinkler device, a fire alarm, a thermostat, a streetlamp, a toaster, a sporting goods, a hot water tank, a heater, a boiler, etc.). According to some embodiments, an electronic device may include at least one of a part of furniture or a building/structure, an electronic board, an electronic signature receiving device, a projector, and various types of measuring instruments (e.g., a water meter, an electric meter, a gas meter, a radio wave meter, and the like). In various embodiments, the electronic device may be flexible, or may be a combination of one or more of the aforementioned various devices. The electronic device according to one embodiment is not limited to the above described devices. In the present disclosure, the term “user” may indicate a person using an electronic device or a device (e.g., an artificial intelligence electronic device) using an electronic device.

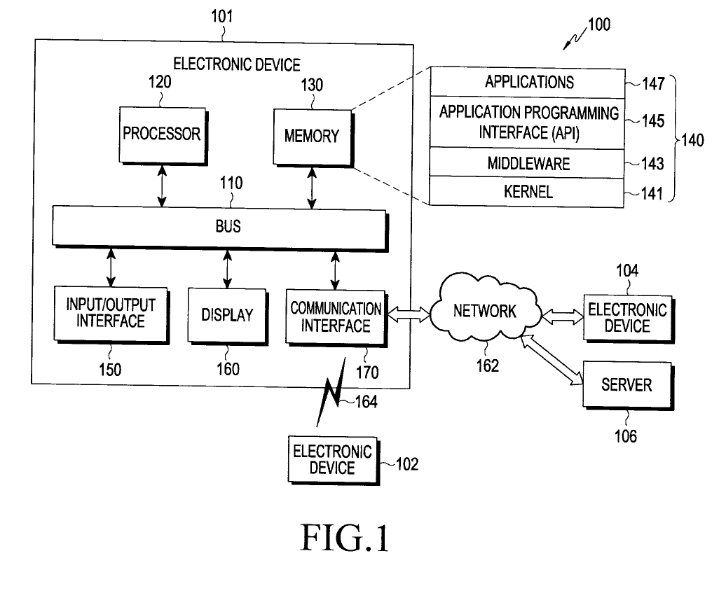

An electronic device 101 within a network environment 100 according to an embodiment will be described with reference to FIG. 1. The electronic device 101 may include a bus 110, a processor 120, a memory 130, an input/output interface 150, a display 160, and a communication interface 170. In some embodiments, the electronic device 101 may omit at least one of the elements, or may further include other elements.

The bus 110 may include, for example, a circuit that interconnects the elements 110 to 170 and transmits communication (for example, control messages or data) between the elements.

The processor 1may include one or more of a central processing unit, an application processor, and a Communication Processor (CP). The processor 120 may carry out, for example, operations or data processing relating to the control and/or communication of at least one other element of the electronic device 101. The processor 120 may include a microprocessor or any suitable type of processing circuitry, such as one or more general-purpose processors (e.g., ARM-based processors), a Digital Signal Processor (DSP), a Programmable Logic Device (PLD), an Application-Specific Integrated Circuit (ASIC), a Field-Programmable Gate Array (FPGA), a Graphical Processing Unit (GPU), a video card controller, etc. In addition, it would be recognized that when a general purpose computer accesses code for implementing the processing shown herein, the execution of the code transforms the general purpose computer into a special purpose computer for executing the processing shown herein. Certain of the functions and steps provided in the Figures may be implemented in hardware, software or a combination of both and may be performed in whole or in part within the programmed instructions of a computer. No claim element herein is to be construed under the provisions of 35 U.S.C. 112(f), unless the element is expressly recited using the phrase “means for.” In addition, an artisan understands and appreciates that a “processor” or “microprocessor” may be hardware in the claimed disclosure. Under the broadest reasonable interpretation, the appended claims are statutory subject matter in compliance with 35 U.S.C. § 101.

The memory 130 may include volatile and/or non-volatile memory. The memory 130 may store, for example, instructions or data relevant to at least one other element of the electronic device 101. According to an embodiment, the memory 130 may store software and/or a program 140. According to an embodiment, the memory 130 may store, for example, a first transmission signal corresponding to a first band, which is one of several transmission bands, of a first communication scheme, a second transmission signal of a second communication scheme corresponding to a second band that is one of several of the transmission bands, or an output voltage of the first transmission signal or the second transmission signal. According to an embodiment, the memory 130 may store a plurality of predetermined threshold voltages or a plurality of predetermined threshold powers. According to an embodiment, the memory 130 may store a first adaptive voltage corresponding to the output voltage of the first transmission signal, where the first adaptive voltage may be in the form of a stepwise signal and may be generated based on the plurality of predetermined threshold voltages or the plurality of predetermined threshold powers. The memory may further store a second adaptive voltage corresponding to the output voltage of the second transmission signal, where the second adaptive voltage may be in the form of a stepwise signal and may be generated based on the plurality of predetermined threshold voltages or the plurality of predetermined threshold powers. For example, the first adaptive voltage or the second adaptive voltage corresponding to the plurality of predetermined threshold voltages or the plurality of predetermined threshold powers may be stored in the memory 130 as tables. According to an embodiment, the memory 130 may store a first baseband transmission signal corresponding to the first transmission signal or a second baseband transmission signal corresponding to the second transmission signal. The memory 130 may store a baseband transmission signal, which is obtained by merging the first baseband transmission signal and the second baseband transmission signal. The memory 130 may also store an envelope voltage (V_{E}) corresponding to an output voltage of the merged baseband transmission signal.

The program 140 may include, for example, a kernel 141, middleware 143, an application programming interface (API) 145, and/or applications (or “apps”) 147. At least some of the kernel 141, the middleware 143, and the API 145 may be referred to as an operating system. The kernel 141 may control or manage system resources (for example, the bus 110, the processor 120, or the memory 130) used for executing an operation or function implemented by other programs (for example, the middleware 143, the API 145, or the application 147). Furthermore, the kernel 141 may provide an interface through which the middleware 143, the API 145, or the applications 147 may access the individual elements of the electronic device 101 to control or manage the system resources.

The middleware 143 may function as, for example, an intermediary for allowing the API 145 or the applications 147 to communicate with the kernel 141 to exchange data. Furthermore, the middleware 143 may process one or more task requests, which are received from the applications 147, according to priorities thereof. For example, the middleware 143 may assign priorities for using the system resources (for example, the bus 110, the processor 120, the memory 130, or the like) of the electronic device 101 to one or more of the applications 147, and may process the one or more task requests. The API 145 is an interface through which the applications 147 control functions provided from the kernel 141 or the middleware 143, and may include, for example, at least one interface or function (for example, instruction) for file control, window control, image processing, or text control. For example, the input/output interface 150 may forward instructions or data, input from a user or an external device, to the other element(s) of the electronic device 101, or may output instructions or data, received from the other element(s) of the electronic device 101, to the user or the external device.

The display 160 may include, for example, a Liquid Crystal Display (LCD), a Light Emitting Diode (LED) display, an Organic Light Emitting Diode (OLED) display, a Micro Electro Mechanical System (MEMS) display, or an electronic paper display. The display 160 may display, for example, various types of contents (for example, text, images, videos, icons, symbols, and the like) for a user. The display 160 may include a touch screen and may receive, for example, a touch, gesture, proximity, or hovering input using an electronic pen or the user's body part. The communication interface 170, for example, may set communication between the electronic device 101 and an external device (e.g., a first external electronic device 102, a second external electronic device 104, or a server 106). For example, the communication interface 170 may be connected to a network 162 through wireless or wired communication to communicate with the external device (for example, the second external electronic device 104 or the server 106).

The wireless communication may include, for example, a cellular communication that uses at least one of LTE, LTE-Advance (LTE-A), code division multiple access (CDMA), wideband CDMA (WCDMA), universal mobile telecommunications system (UMTS), wireless broadband (WiBro), global system for mobile communications (GSM), or the like. According to an embodiment, like the short-range communication 164 illustrated in FIG. 1, the wireless communication may include, for example, at least one of Wi-Fi, Li-Fi (Light Fidelity), Bluetooth, Bluetooth Low Energy (BLE), ZigBee, Near Field Communication (NFC), magnetic secure transmission, Radio Frequency (RF), and Body Area Network (BAN). According to an embodiment, the wireless communication may include a GNSS. The GNSS may be, for example, a Global Positioning System (GPS), a Global navigation satellite system (GLONASS), a BeiDou navigation satellite system (hereinafter, referred to as “BeiDou”), or Galileo (the European global satellite-based navigation system). Hereinafter, in this document, the term “GPS” may be interchangeable with the term “GNSS”. The wired communication may include, for example, at least one of a Universal Serial Bus (USB), a High Definition Multimedia Interface (HDMI), Recommended Standard 232 (RS-232), a Plain Old Telephone Service (POTS), and the like. The network 162 may include a telecommunications network, for example, at least one of a computer network (for example, a LAN or a WAN), the Internet, and a telephone network.

Each of the first and second external electronic devices 102 and 104 may be of the same or a different type from the electronic device 101. According to various embodiments, all or some of the operations executed in the electronic device 101 may be executed in another electronic device or a plurality of electronic devices (for example, the electronic devices 102 and 104 or the server 106). According to an embodiment, when the electronic device 101 has to perform some functions or services automatically or in response to a request, the electronic device 101 may make a request for performing at least some functions relating thereto to another device (for example, the electronic device 102 or 104 or the server 106) instead of performing the functions or services by itself or in addition. Another electronic apparatus may execute the requested functions or the additional functions, and may deliver a result of the execution to the electronic apparatus 101. The electronic device 101 may provide the received result as it is, or may additionally process the received result to provide the requested functions or services. To this end, for example, cloud computing, distributed computing, or client-server computing technology may be used.

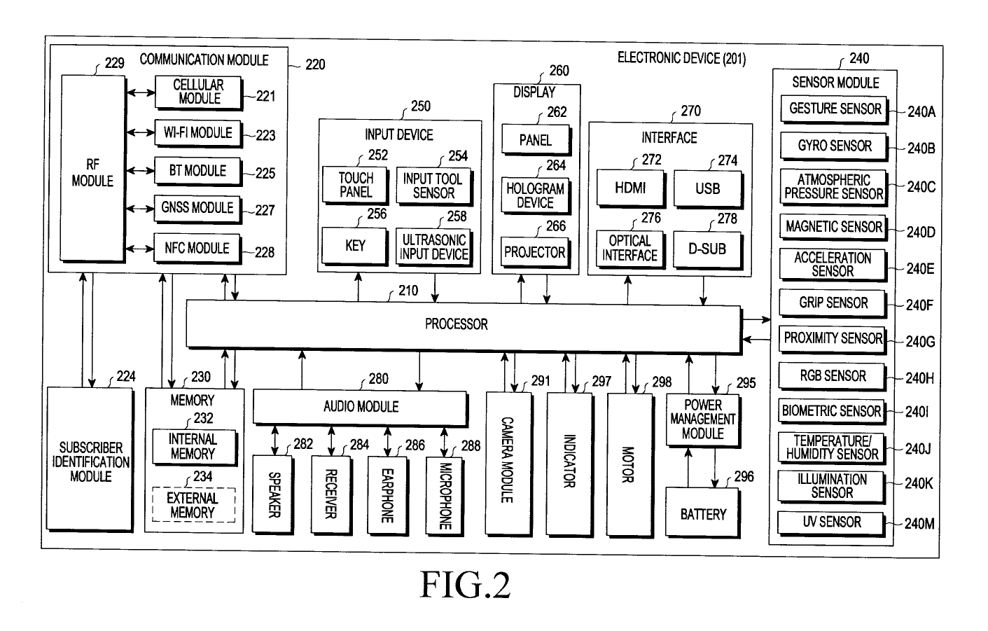

FIG. 2 is a block diagram of an electronic device 201 according to an embodiment. The electronic device 201 may include, for example, the whole or part of the electronic device 101 illustrated in FIG. 1. The electronic device 201 may include at least one processor 210 (for example, an AP), a communication module 220, a subscriber identification module 224, a memory 230, a sensor module 240, an input device 250, a display 260, an interface 270, an audio module 280, a camera module 291, a power management module 295, a battery 296, an indicator 297, and a motor 298. The processor 210 may control a plurality of hardware or software elements connected thereto and may perform various data processing and operations by driving an operating system or an application. The processor 210 may be implemented by, for example, a System on Chip (SoC). According to an embodiment, the processor 210 may further include a graphic processing unit (GPU) and/or an image signal processor. The processor 210 may also include at least some of the elements illustrated in FIG. 2 (for example, a cellular module 221). The processor 210 may load, in volatile memory, instructions or data received from at least one of the other elements (for example, non-volatile memory), process the loaded instructions or data, and store the resultant data in the non-volatile memory.

The communication module 220 may have a configuration that is the same as, or similar to, that of the communication interface 170. The communication module 220 may include, for example, a cellular module 221, a Wi-Fi module 223, a Bluetooth module 225, a GNSS module 227, an NFC module 228, and an RF module 229. The cellular module 221 may provide, for example, a voice call, a video call, a text message service, an Internet service, or the like through a communication network. According to an embodiment, the cellular module 221 may identify and authenticate the electronic device 201 within a communication network using the subscriber identification module 224 (for example, a SIM card). According to an embodiment, the cellular module 221 may perform at least some of the functions that the processor 210 may provide. According to an embodiment, the cellular module 221 may include a communication processor (CP). According to some embodiments, at least some (for example, two or more) of the cellular module 221, the Wi-Fi module 223, the BT module 225, the GNSS module 227, and the NFC module 228 may be included in one Integrated Chip (IC) or IC package. The RF module 229 may transmit/receive, for example, a communication signal (for example, an RF signal). The RF module 229 may include, for example, a transceiver, a Power Amp Module (PAM), a frequency filter, a Low-Noise Amplifier (LNA), an antenna, or the like. According to another embodiment, at least one of the cellular module 221, the Wi-Fi module 223, the BT module 225, the GPS module 227, and the NFC module 228 may transmit/receive an RF signal through a separate RF module. The subscriber identification module 224 may include, for example, a card that includes a subscriber identity module and/or an embedded SIM, and may contain unique identification information (for example, an Integrated Circuit Card Identifier (ICCID)) or subscriber information (for example, an International Mobile Subscriber Identity (IMSI)).

The memory 230 (for example, the memory 130) may include, for example, an internal memory 232 or an external memory 234. The internal memory 232 may include, for example, at least one of a volatile memory (for example, a DRAM, an SRAM, an SDRAM, or the like) and a non-volatile memory (for example, a One Time Programmable ROM (OTPROM), a PROM, an EPROM, an EEPROM, a mask ROM, a flash ROM, a flash memory, a hard disc drive, or a Solid State Drive (SSD)). The external memory 234 may include a flash drive, for example, a compact flash (CF), a secure digital (SD), a Micro-SD, a Mini-SD, an eXtreme digital (xD), a multi-media card (MMC), a memory stick, and the like. The external memory 234 may be operationally, functionally and/or physically connected to the electronic device 201 through various interfaces.

The sensor module 240 may, for example, measure a physical quantity or detect the operating state of the electronic device 201 and may convert the measured or detected information into an electrical signal. The sensor module 240 may include, for example, at least one of a gesture sensor 240A, a gyro sensor 240B, an atmospheric pressure sensor 240C, a magnetic sensor 240D, an acceleration sensor 240E, a grip sensor 240F, a proximity sensor 240G a color sensor 240H (for example, a red, green, blue (RGB) sensor), a biometric sensor 2401, a temperature/humidity sensor 240J, an illumination sensor 240K, and a ultraviolet (UV) sensor 240M. Additionally or alternatively, the sensor module 240 may include, for example, an e-nose sensor, an electromyography (EMG) sensor, an electroencephalogram (EEG) sensor, an electrocardiogram (ECG) sensor, an infrared (IR) sensor, an iris sensor, and/or a fingerprint sensor. The sensor module 240 may further include a control circuit for controlling one or more sensors included therein. In some embodiments, the electronic device 201 may further include a processor, which is configured to control the sensor module 240, as a part of the processor 210 or separately from the processor 210 in order to control the sensor module 240 while the processor 210 is in a sleep state.

The input device 250 may include, for example, a touch panel 252, a (digital) pen sensor 254, a key 256, or an ultrasonic input device 258. The touch panel 252 may use, for example, at least one of a capacitive type, a resistive type, an infrared type, and an ultrasonic type. Furthermore, the touch panel 252 may further include a control circuit. The touch panel 252 may further include a tactile layer to provide a tactile reaction to a user. The (digital) pen sensor 254 may include, for example, a recognition sheet that is a part of, or separate from, the touch panel. The key 256 may include, for example, a physical button, an optical key, or a keypad. The ultrasonic input device 258 may detect ultrasonic waves, which are generated by an input tool, through a microphone (for example, a microphone 288) to identify data corresponding to the detected ultrasonic waves.

The display 260 (for example, the display 160) may include a panel 262, a hologram device 264, a projector 266, and/or a control circuit for controlling them. The panel 262 may be implemented to be, for example, flexible, transparent, or wearable. The panel 262, together with the touch panel 252, may be configured as one or more modules. According to an embodiment, the panel 262 may include a pressure sensor (or a POS sensor) which may measure a strength of pressure of a user's touch. The pressure sensor may be implemented so as to be integrated with the touch panel 252 or may be implemented as one or more sensors separate from the touch panel 252. The hologram device 264 may show a three dimensional image in the air by using an interference of light. The projector 266 may display an image by projecting light onto a screen. The screen may be located, for example, in the interior of, or on the exterior of, the electronic device 201. The interface 270 may include, for example, an HDMI 272, a USB 274, an optical interface 276, or a D-subminiature (D-sub) 278. The interface 270 may be included in, for example, the communication circuit 170 illustrated in FIG. 1. Additionally or alternatively, the interface 270 may, for example, include a mobile high-definition link (MHL) interface, a secure digital (SD) card/multi-media card (MMC) interface, or an infrared data association (IrDA) standard interface.

The audio module 280 may bidirectionally convert, for example, sound and an electric signal. At least some elements of the audio module 280 may be included, for example, in the input/output interface 145 illustrated in FIG. 1. The audio module 280 may process sound information that is input or output through, for example, a speaker 282, a receiver 284, earphones 286, the microphone 288, and the like. The camera module 291 is a device that can photograph a still image and a moving image. According to an embodiment, the camera module 291 may include one or more image sensors (for example, a front sensor or a rear sensor), a lens, an image signal processor (ISP), or a flash (for example, an LED or xenon lamp). The power management module 295 may manage, for example, the power of the electronic device 201. According to an embodiment, the power management module 295 may include a power management integrated circuit (PMIC), a charger IC, or a battery or fuel gauge. The PMIC may use a wired and/or wireless charging method. Examples of the wireless charging method may include a magnetic resonance method, a magnetic induction method, an electromagnetic wave method, and the like. Additional circuits (for example, a coil loop, a resonance circuit, a rectifier, and the like) for wireless charging may be further included. The battery gauge may measure, for example, the residual amount of the battery 296 and a voltage, current, or temperature while charging. The battery 296 may include, for example, a rechargeable battery and/or a solar battery.

The indicator 297 may display a particular state, for example, a booting state, a message state, a charging state, or the like of the electronic device 201 or a part (for example, the processor 210) of the electronic device 201. The motor 298 may convert an electrical signal into a mechanical vibration and may generate a vibration, a haptic effect, or the like. The electronic device 201 may include a mobile TV support device that can process media data according to a standard, such as digital multimedia broadcasting (DMB), digital video broadcasting (DVB), mediaFlo™, and the like. Each of the above-described component elements of hardware according to the present disclosure may be configured with one or more components, and the names of the corresponding component elements may vary based on the type of electronic device. In various embodiments, an electronic device (for example, the electronic device 201) may omit some elements or may further include additional elements, or some of the elements of the electronic device may be combined with each other to configure one entity, in which case the electronic device may identically perform the functions of the corresponding elements prior to the combination.

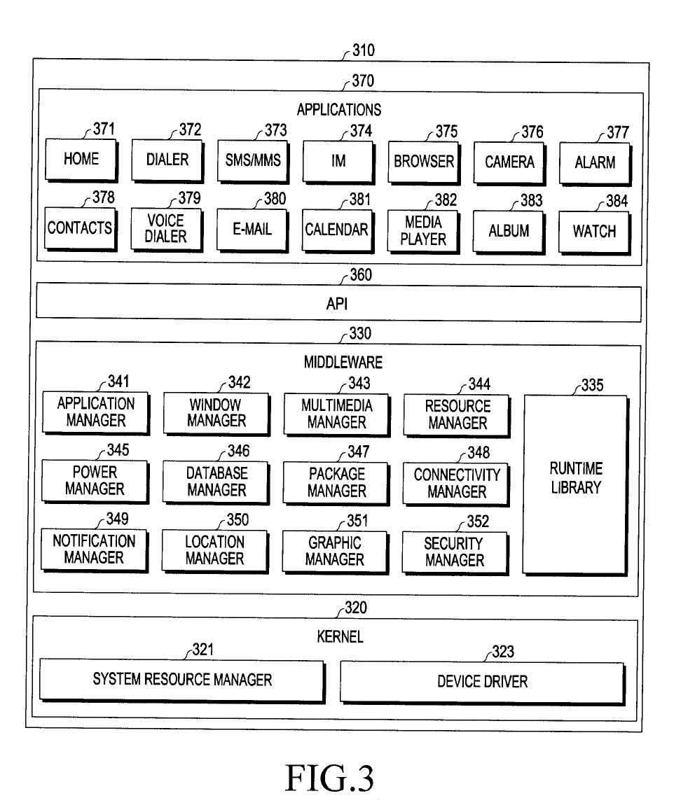

FIG. 3 is a block diagram of a program module according to an embodiment. According to an embodiment, the program module 310 (for example, the program 140) may include an Operating System (OS) that controls resources relating to an electronic device (for example, the electronic device 101) and/or various applications (for example, the applications 147) that are driven on the operating system. The operating system may include, for example, Android™, iOS™, Windows™, Symbian™, Tizen™, or Bada™. Referring to FIG. 3, the program module 310 may include a kernel 320 (for example, the kernel 141), middleware 330 (for example, the middleware 143), an API 360 (for example, the API 145), and/or applications 370 (for example, the applications 147). At least a part of the program module 310 may be preloaded on the electronic device, or may be downloaded from an external electronic device (for example, the electronic device 102 or 104 or the server 106).

The kernel 320 may include, for example, a system resource manager 321 and/or a device driver 323. The system resource manager 321 may control, allocate, or retrieve system resources. According to an embodiment, the system resource manager 321 may include a process manager, a memory manager, or a file system manager. The device driver 323 may include, for example, a display driver, a camera driver, a Bluetooth driver, a shared memory driver, a USB driver, a keypad driver, a Wi-Fi driver, an audio driver, or an Inter-Process Communication (IPC) driver. The middleware 330 may provide, for example, a function required by the applications 370 in common, or may provide various functions to the applications 370 through the API 360 such that the applications 370 can efficiently use limited system resources within the electronic device. According to an embodiment, the middleware 330 may include at least one of a runtime library 335, an application manager 341, a window manager 342, a multi-media manager 343, a resource manager 344, a power manager 345, a database manager 346, a package manager 347, a connectivity manager 348, a notification manager 349, a location manager 350, a graphic manager 351, and a security manager 352.

The runtime library 335 may include, for example, a library module that a compiler uses in order to add a new function through a programming language while the applications 370 are being executed. The runtime library 335 may manage an input/output, manage a memory, or process an arithmetic function. The application manager 341 may manage, for example, the life cycles of the applications 370. The window manager 342 may manage GUI resources used for a screen. The multimedia manager 343 may identify formats required for reproducing various media files and may encode or decode a media file using a codec suitable for the corresponding format. The resource manager 344 may manage the source code of the applications 370 or the space in memory. The power manager 345 may mange, for example, capacity, temperature, or power of the battery, and may determine or provide power information required for the operation of the electronic device based on corresponding information. According to an embodiment, the power manager 345 may operate in conjunction with a basic input/output system (BIOS). The database manager 346 may, for example, generate, search, or change databases to be used by the applications 370. The package manager 347 may manage the installation or update of an application that is distributed in the form of a package file.

The connectivity manager 348 may manage, for example, a wireless connection. The notification manager 349 may provide information on an event (for example, an arrival message, an appointment, a proximity notification, or the like) to a user. The location manager 350 may manage, for example, the location information of the electronic device. The graphic manager 351 may manage a graphic effect to be provided to a user and a user interface relating to the graphic effect. The security manager 352 may provide, for example, system security or user authentication. According to an embodiment, the middleware 330 may include a telephony manager for managing a voice or video call function of the electronic device or a middleware module that is capable of forming a combination of the functions of the above-described elements. According to an embodiment, the middleware 330 may provide specialized modules according to the types of operation systems. Furthermore, the middleware 330 may dynamically remove some of the existing elements, or may add new elements. The API 360 is, for example, a set of API programming functions, and may be provided with different configurations depending on the operating system. For example, in the case of Android or iOS, one API set may be provided for each platform, and in the case of Tizen, two or more API sets may be provided for each platform.

The applications 370 may include, for example, a home application 371, a dialer application 372, an SMS/MMS application 373, an instant messaging (IM) application 374, a browser application 375, a camera application 376, an alarm application 377, a contact application 378, a voice dial application 379, an email application 380, a calendar application 381, a media player application 382, an album application 383, a watch application 384, a health-care application (for example, for measuring exercise quantity or blood glucose), or an application providing environmental information (for example, atmospheric pressure, humidity, or temperature information). According to an embodiment, the applications 370 may include an information exchange application that can support the exchange of information between the electronic device and an external electronic device. The information exchange application may include, for example, a notification relay application for relaying particular information to an external electronic device or a device management application for managing an external electronic device. For example, the notification relay application may relay notification information generated in the other applications of the electronic device to an external electronic device, or may receive notification information from an external electronic device to provide the received notification information to a user. The device management application may install, delete, or update the functions (for example, turning on/off the external electronic device itself (or some elements thereof) or adjusting the brightness (or resolution) of a display) of an external electronic device that communicates with the electronic device or applications executed in the external electronic device. According to an embodiment, the applications 370 may include applications (for example, a health care application of a mobile medical appliance) that are designated according to the attributes of an external electronic device. According to an embodiment, the applications 370 may include applications received from an external electronic device. At least some of the program module 310 may be implemented (for example, executed) by software, firmware, hardware (for example, the processor 210), or a combination of two or more thereof and may include a module, a program, a routine, an instruction set, or a process for performing one or more functions.

The term “module” as used herein may include a unit consisting of hardware, software, or firmware, and may, for example, be used interchangeably with the term “logic,” “logical block,” “component,” “circuit,” or the like. A “module” may be an integrated component, or a part thereof for performing one or more functions. A “module” may be mechanically or electronically implemented and may include, for example, an Application-Specific Integrated Circuit (ASIC) chip, a Field-Programmable Gate Arrays (FPGA), or a programmable-logic device, which has been known or are to be developed in the future, for performing certain operations. At least some aspects of devices (e.g., modules or functions thereof) or methods (e.g., operations) according to various embodiments may be implemented by an instruction which is stored a computer-readable storage medium (e.g., the memory 130) in the form of a program module. The instruction, when executed by a processor (e.g., the processor 120), may cause the one or more processors to execute the function corresponding to the instruction. The computer-readable storage medium may include a hard disk, a floppy disk, a magnetic medium (e.g., a magnetic tape), an Optical Media (e.g., CD-ROM, DVD), a Magneto-Optical Media (e.g., a floptical disk), an inner memory, etc. The instruction may include code made by a compiler or code executable by an interpreter. The programming module according to the present disclosure may include one or more of the aforementioned components or may further include other additional components, or some of the aforementioned components may be omitted. Operations performed by a module, a programming module, or other elements according to various embodiments may be executed sequentially, in parallel, repeatedly, or in a heuristic manner. At least some operations may be executed according to another sequence, may be omitted, or may further include other operations.

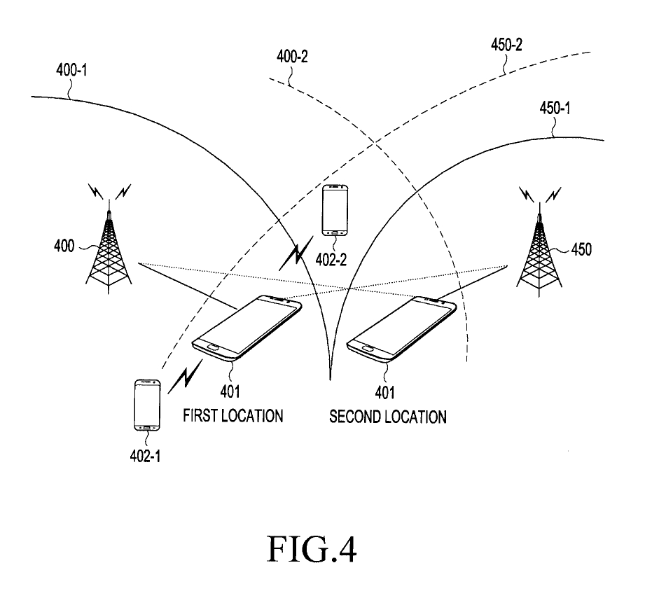

FIG. 4 illustrates a wireless communication scheme of an electronic device according to an embodiment. The electronic device 401 or the external electronic device 402-1 or 402-2 of FIG. 4 may include some or all of the electronic device 101 illustrated in FIG. 1 or the electronic device 201 illustrated in FIG. 2.

Referring to FIG. 4, when the electronic device 401 is positioned at a first location within an internal coverage 400-1 of a first BS 400, the electronic device 401 may access and communicate with the first BS 400, and the internal coverage 400-1 corresponding to the first BS 400 may be referred to as a serving cell with respect to the electronic device 401 at the first location. However, when the electronic device 401 moves to a second location within an internal coverage 450-1 of a second BS 450 and is between the internal coverage 400-1 and an external coverage 400-2 of the first BS 400, the electronic device 401 cannot access and communicate with the first BS 400 but can receive signals from the first BS 400, and the internal coverage 400-1 corresponding to the first BS 400 may be referred to as a neighbor cell with respect to the electronic device 401 at the second location. Similarly, when the electronic device 401 is positioned at the second location within the internal coverage 450-1 of the second BS 450, the electronic device 401 may access and communicate with the second BS 450, and the internal coverage 450-1 corresponding to the second BS 450 may be referred to as a serving cell with respect to the electronic device 401 at the second location. However, when the electronic device 401 moves back to the first location, which is within the internal coverage 400-1 of the first BS 400 and is between the internal coverage 450-1 and the external coverage 450-2 of the second BS 450, the electronic device 401 cannot access and communicate with the second BS 450 but can receive signals from the second BS 450, and the internal coverage 450-1 corresponding to the second BS 450 may be referred to as a neighbor cell with respect to the electronic device 401 at the first location. As described above, the serving cell and the neighbor cell may be relative concepts. One electronic device 401 may belong to the internal coverage of one BS and belong to the external coverage of a plurality of other BSs.

According to an embodiment, the electronic device 401 may access and communicate with the BS (for example, the first BS 400 or the second BS 450), to which the electronic device 401 pertains, through a first communication scheme (for example, a cellular communication network scheme), and also communicate with the external electronic devices 402-1 and 402-2 adjacent to the electronic device 401 through a second communication scheme (for example, Device-to-Device (D2D) communication based on cellular communication).

According to an embodiment, when the electronic device 401 at the first location accesses the first BS 400 through the first communication scheme (for example, cellular communication network scheme) and also desires to communicate with the external electronic device 402-1 positioned within the internal coverage 400-1 of the first BS 400 through the second communication scheme (for example, D2D communication based on the cellular communication), the electronic device 401 may simultaneously transmit a first transmission signal of the first communication scheme and a second transmission signal of the second communication scheme. According to an embodiment, both the first transmission signal and the second transmission signal may use a transmission band (for example, the uplink band of a cellular communication network) of the first communication scheme. According to an embodiment, the transmission band of the first communication scheme may be an LTE UpLink (UL) band.

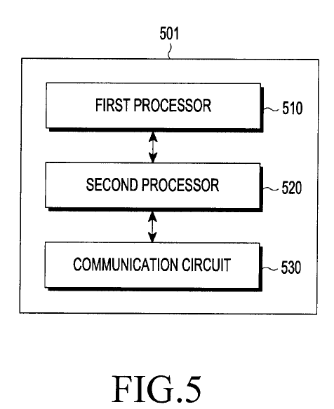

FIG. 5 is a block diagram of an electronic device according to an embodiment.

Referring to FIG. 5, an electronic device 501 may include at least one of a first processor 510, a second processor 520, and a communication circuit 530. Only elements relevant to the description below are illustrated in FIG. 5, and it is apparent that the electronic device may also include other elements in addition to the aforementioned elements. For example, the electronic device 501 of FIG. 5 may include some or all of the electronic device 101 illustrated in FIG. 1, the electronic device 201 illustrated in FIG. 2, or the electronic device 401 illustrated in FIG. 4.

According to an embodiment, the first processor 510 may control the overall operations of the electronic device 501. The first processor 510 may include some or all of the processor 120 illustrated in FIG. 1 or the processor 210 illustrated in FIG. 2.

According to an embodiment, the first processor 510 may be an Application Processor (AP).

According to an embodiment, the first processor 510 may receive, from a user, an input of selecting or executing applications for communication based on the first communication scheme or the second communication scheme. For example, when a signal for selecting or executing a first application of the first communication scheme or a second application of the second communication scheme is input, the first processor 510 may transfer the signal to the second processor 520. The second processor 520 may perform controls to communicate with an external electronic device in the first communication scheme or the second communication scheme through the communication circuit 530, depending on the signal transferred from the first processor 510.

According to an embodiment, the first communication scheme may be a communication scheme through the communication network, for example, a cellular communication network scheme. The cellular communication network scheme may include, for example, Long-Term Evolution (LTE) or LTE-Advanced (LTE-A).

According to an embodiment, the second communication scheme may be Device-to-Device (D2D) communication scheme such as cellular-based D2D communication. The cellular-based D2D communication may include, for example, LTE D2D or Proximity based Services (ProSe).

According to an embodiment, the first application may be a broadcast-related application, and the second application may be a message exchange application, an application of exchanging content such as images/videos/audio/documents, or a voice exchange application such as Push To Talk (PTT) or Mission Critical Push To Talk over LTE (MC-PTT). According to an embodiment, the first processor 510 may simultaneously receive two inputs selecting or executing both the first application of the first communication scheme and the second application of the second communication scheme. For example, when a natural disaster occurs, the user of the electronic device 501 may desire to exchange messages, content, or voice signals with another electronic device (for example, the external electronic device 402-1 or 402-2) adjacent thereto through the second application while receiving disaster broadcasts from a broadcasting station (for example, the BS 400 or 450 or the server 106) through the first application. Thus, the user may simultaneously select or execute the first application and the second application. When signals (for example, first signals) for selecting or executing the first application and the second application are simultaneously input, the first processor 510 may transfer the signals to the second processor 520. According the first signals transferred from the first processor 510, the second processor 520 may execute the first application to exchange messages, content, or voice signals with the external electronic device (for example, the external electronic device 402-1 or 402-2 or the electronic device 102) adjacent to the electronic device 501 through the second communication scheme (i.e. direct communication). At the same time, the second processor 520 may execute the second application to transmit and receive disaster-related broadcast through the first communication scheme to/from the communication network (for example, the BS 400 or 450 or the server 106).

According to an embodiment, the first application may be a data transmission/reception application of the first communication scheme, and the second application may be a data transmission/reception application of the second communication scheme. According to an embodiment, the electronic device 501 may perform a relay function. When the relay function is selected, the first processor 510 may simultaneously generate signals (for example, second signals) for selecting or executing the first application of the first communication scheme and the second application of the second communication scheme. For example, the first processor 510 may transfer the signals (for example, second signals), which are simultaneously generated to select or execute the first application and the second application when the relay function is selected, to the second processor 520. According the second signals transferred from the first processor 510, the second processor 520 may execute the first application to transmit and receive data (for example, messages, content, or voice signals) to/from the external electronic device (for example, the external electronic device 402-1 or 402-2 or the electronic device 102) through the second communication scheme (e.g. D2D communication). At the same time, the second processor 520 may execute the second application to transmit and receive data (for example, disaster-related broadcast) through the first communication scheme to/from the communication network (for example, the BS 400 or 450 or the server 106).

According to an embodiment, the second processor 520 may perform controls to transmit and receive data related to the applications executed by the first processor 510 through the communication circuit 530 under the control of the first processor 510. The second processor 520 may include some or all of the processor 120 illustrated in FIG. 1, or the processor 210 or the cellular module 221 illustrated in FIG. 2.

According to an embodiment, the second processor 520 may be a Communication Processor (CP).

According to an embodiment, when the second processor 520 receives an input for selecting or executing the first application or the second application from the first processor 510, the second processor 520 may execute the corresponding application and may transmit and receive signals including data through the first communication scheme or the second communication scheme.

According to an embodiment, the second processor 520 may generate a baseband transmission signal including a data packet related to the application executed by the first processor 510. For example, when the input for selecting or executing the first application of the first communication scheme is received from the first processor 510, the second processor 520 may generate a first baseband signal including a data packet related to the first application of the first communication scheme. When the input for selecting or executing the second application of the second communication scheme is received from the first processor 510, the second processor 520 may generate a second baseband signal including a data packet related to the second application in a second band among the transmission bands (for example, uplink bands) of the first communication scheme.

According to an embodiment, the second processor 520 may transfer the generated first baseband transmission signal or second baseband transmission signal to the communication circuit 530.

According to an embodiment, the communication circuit 530 may transmit and receive data through the first communication scheme or the second communication scheme under the control of the second processor 520. The communication circuit 530 may include some or all of the communication interface 170 illustrated in FIG. 1 or the RF module 229 illustrated in FIG. 2.

According to an embodiment, the communication circuit 530 may establish, for example, communication between the electronic device 501 and an external electronic device (for example, a first external electronic device or a second external electronic device) under the control of the second processor 520.

According to an embodiment, the first external electronic device may be the BS (for example, the BS 400 or 450) of the cellular communication network, the server (for example, the server 106) of the BS 400 or 450, or another electronic device (for example, the electronic device 104) connected through the BS 400 or 450 or the server 106.

According to an embodiment, the second external electronic device may be another electronic device (for example, the electronic device 102 or the electronic device 402-1 or 402-2), which is adjacent to the electronic device 501 and performs cellular-based D2D communication with the electronic device 501.

According to an embodiment, the communication circuit 530 may include a plurality of communication circuits. According to an embodiment, the communication circuit 530 may be referred to as a communication unit or a communication module. According to an embodiment, the communication circuit 530 may include the communication unit or the communication module as the part thereof, or constitute the communication unit or the communication module.

According to an embodiment, the communication circuit 530 may generate a transmission signal by converting the baseband transmission signal transferred from the second processor 520 into a wireless signal and transmit the generated transmission signal through the first communication scheme or the second communication scheme. In addition, the communication circuit 530 may convert a wireless signal received through the first communication scheme or the second communication scheme into a baseband transmission signal and transfer the converted baseband transmission signal to the second processor 520.

According to an embodiment, the communication circuit 530 may convert a first baseband transmission signal related to the first application or a second baseband transmission signal related to the second application, which is transferred from the second processor 520, into a wireless signal of a first transmission signal or a second transmission signal, and transmit the converted first transmission signal to a first external electronic device through the first communication scheme or the converted second transmission signal to a second external electronic device through the second communication scheme.

According to an embodiment, when an input for simultaneously transmitting the first transmission signal and the second transmission signal is transferred from the second processor 520, the communication circuit 530 may combine the first transmission signal and the second transmission signal, amplify the combined transmission signal through a power amplifier (not shown), and transmit the combined amplified first transmission and second transmission signal.

According to an embodiment, the communication circuit 530 may convert a first reception signal received from the first external electronic device through the first communication scheme or a second reception signal received from the second external electronic device through the second communication scheme into a first baseband reception signal or a second baseband reception signal. The communication circuit 530 may further transfer the converted baseband reception signal to the second processor 520. The second processor 520 may transfer the converted first baseband reception signal or the converted second baseband reception signal to the first processor 510. The first processor 510 may decode the data included in the converted first baseband reception signal or the converted second baseband reception signal to recover, for example, image signals or voice signals. The first processor 510 may store the recovered data in the memory (for example, the memory 130) or display the recovered data on the display (for example, the display 160).

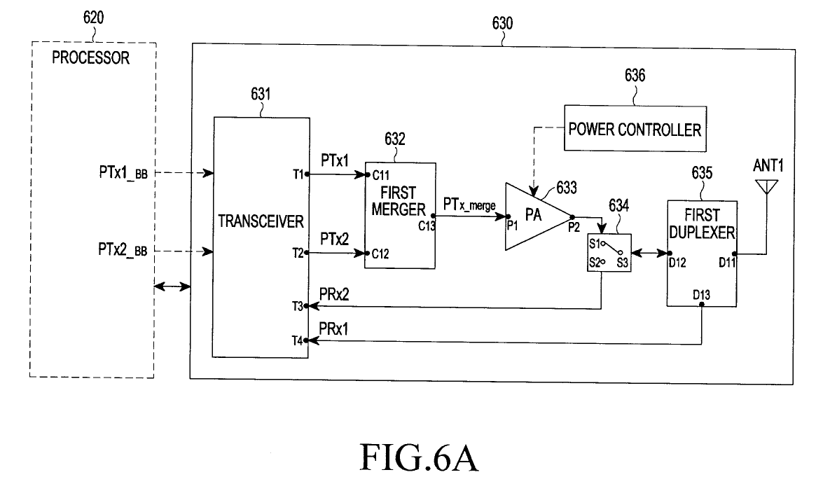

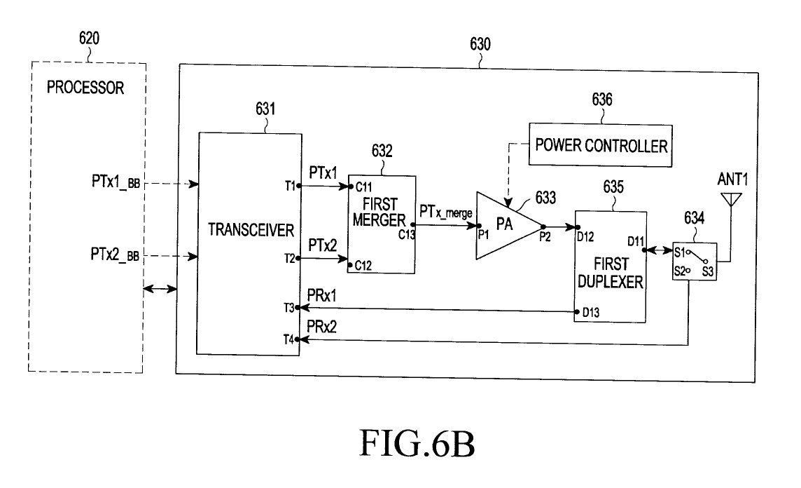

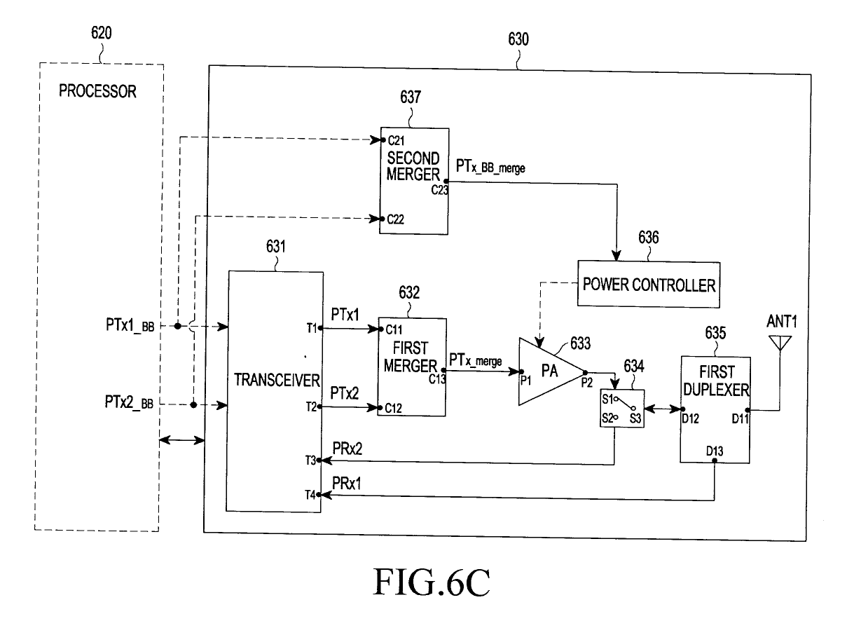

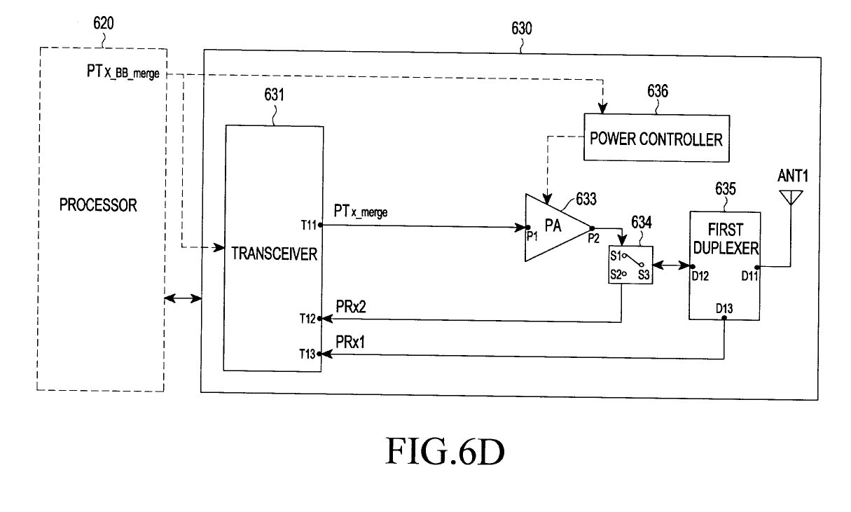

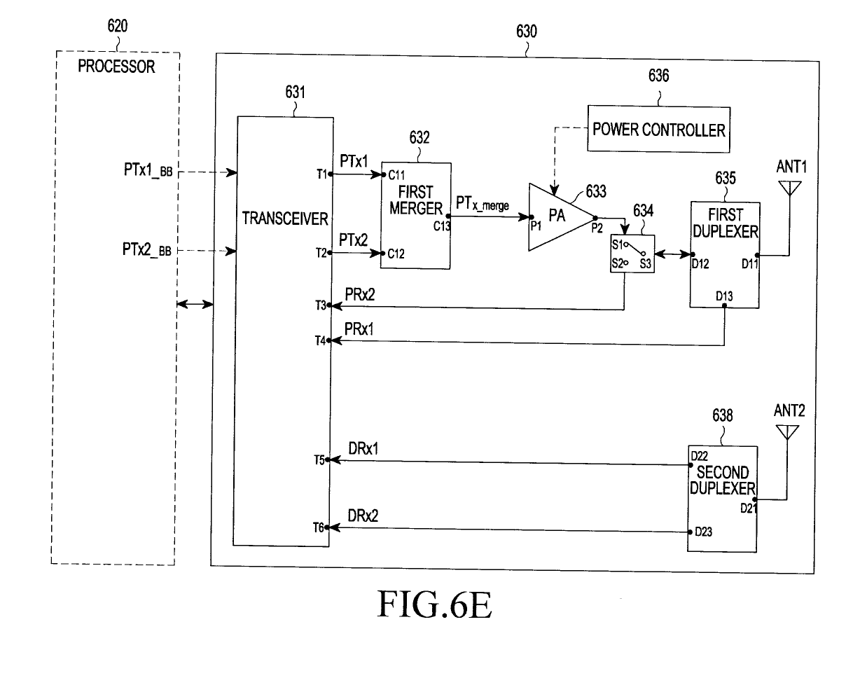

The second processor 520 and the communication circuit 530 will be described below in more detail with reference to FIGS. 6A to 6E.

FIGS. 6A to 6E are block diagrams illustrating a communication circuit of an electronic device according to various embodiments. In FIGS. 6A to 6E, the processor 620 may include some or all of the second processor 520 illustrated in FIG. 5, and the communication circuit 630 may include some or all of the communication circuit 530 illustrated in FIG. 5.

Referring to FIG. 6A, the communication circuit 630 operationally connected to the processor 620 of the electronic device (for example, the electronic device 501) according to an embodiment may include at least one of a transceiver 631, a first merger 632, a Power Amplifier (PA) 633, a switch 634, a first duplexer 635, a first antenna ANT1, and a power controller 636.

According to an embodiment, the transceiver 631 may convert a baseband transmission signal provided from the processor 620 into a wireless signal or convert a wireless signal received through the antenna (for example, the first antenna (ANT1)) into a baseband reception signal. For example, the transceiver 631 may convert a first baseband transmission signal (for example, PTx1_{—BB}) of the first communication scheme into a wireless signal of the first transmission signal (for example, PTx1) corresponding to a first band that is one of the plurality of transmission bands (for example, uplink bands of the cellular communication network) of the first communication scheme. The transceiver may also convert a second baseband transmission signal (for example, PTx2_{—BB}) of the second communication scheme into a second transmission signal (for example, PTx2) corresponding to a second band.

According to an embodiment, the transceiver 631 may convert the wireless signal of the first reception signal (for example, PRx1) of the first communication scheme corresponding to reception bands (for example, downlink bands of the cellular communication network) of the first communication scheme into a first baseband reception signal (not shown). The transceiver 631 may also convert the second reception signal (for example, PRx2) of the second communication scheme corresponding to the second band, which is received through the first antenna (ANT1), into a second baseband reception signal (not shown). The transceiver 631 may transfer the converted first baseband reception signal or the converted second baseband reception signal to the processor 620. The processor 620 may transfer the first baseband reception signal or the second baseband reception signal to an application processor (for example, the first processor 510) (not shown in FIG. 6A). The application processor may decode data included in the first baseband reception signal or the second baseband reception signal to recover data such as image signals or voice signals. The application processor (for example, the first processor 510) may store the recovered data in the memory (for example, the memory 130) or display the recovered data on the display (for example, the display 160).

According to an embodiment, the transmission bands of the first communication scheme may be LTE UpLink (UL) bands. According to an embodiment, the reception bands of the first communication scheme may be LTE DownLink (DL) bands.

According to an embodiment, the first transmission signal PTx1 may include LTE UL transmission data corresponding to a first band, which is one of the LTE UL bands. According to an embodiment, the second transmission signal PTx2 may include LTE D2D transmission data corresponding to a second band, which is also one of the LTE UL bands. According to an embodiment, the first reception signal PRx1 may include LTE DL reception data corresponding to at least one of the LTE DL bands. According to an embodiment, the second reception data PRx2 may include LTE D2D reception data corresponding to at least one of the LTE UL bands.

According to an embodiment, the transceiver 631 may include a first port T1 for transmitting the first transmission signal PTx1, a second port T2 for transmitting the second transmission signal PTx2, a third port T3 for receiving the second reception signal PRx2, and a fourth port T4 for receiving the first reception signal PRx1.

According to an embodiment, the first merger 632 may merge the first transmission signal PTx1 and the second transmission signal PTx2. According to an embodiment, the first merger 632 may merge the first band of the first transmission signal PTx1 and the second band of the second transmission signal PTx2. According to an embodiment, the first merger 632 may be integrated into the transceiver 631.

According to an embodiment, the first merger 632 may include a first input terminal C11 electrically connected to the first port T1 of the transceiver 631, a second input terminal C12 electrically connected to the second port T2 of the transceiver 631, and an output terminal C13. The first merger 632 may output, through the output terminal C13, the first transmission signal PTx1 input through the first input terminal C11. The first merger 632 may output, through the output terminal C13, the second transmission signal PTx2 input through the second input terminal C12. The first merger 632 may merge the first transmission signal PTx1 input through the first input terminal C11 and the second transmission signal PTx2 input through the second input terminal C12 and output the combined signal (for example, PTx1+PTx2=PTx_{—merge}) through the output terminal C13.

According to an embodiment, the PA 633 may amplify the signal obtained by merging the first transmission signal PTx1 and the second transmission signal PTx2. According to an embodiment, the operation voltage of the PA 633 may be controlled through the processor 620 or the power controller 636.

According to an embodiment, the PA 633 may include the input terminal P1 electrically connected to the output terminal C13 of the first merger 632 and the output terminal P2. The

PA 633 may amplify the first transmission signal PTx1 input through the input terminal P1 and output the amplified first transmission signal through the output terminal P2. The PA 633 may amplify the second transmission signal PTx2 input through the input terminal P1 and output the amplified second transmission signal through the output terminal P2. The PA 633 may amplify the signal PTx_{—merge} obtained by merging the first transmission signal PTx1 and the second transmission signal PTx2 and input through the input terminal P1, and output the signal through the output terminal P2.

According to an embodiment, the switch 634 may switch between a reception path for when the second reception signal PRx2 corresponding to the second band is received and a transmission path for when the first transmission signal PTx1 or the second transmission signal PTx2 is transmitted. According to an embodiment, the switch 634 may perform switching such that the PA 633 is connected to the first duplexer 635 in one switch state and the transceiver 631 is connected to the first duplexer 635 in another switch state. For example, the switch 634 may perform switching such that the PA 633 is connected to the first duplexer 635 when the first transmission signal PTx1 or the second transmission signal PTx2 is transmitted and such that the transceiver 631 is connected to the first duplexer 635 when the second reception signal PRx2 is received.

According to an embodiment, the switch 634 may include a first terminal S1 electrically connected to the output terminal P2 of the PA 633, a second terminal S2 electrically connected to the third port T3 of the transceiver 631, and a third terminal S3 electrically connected to the first duplexer 635 (which in turn connects to the first antenna ANT1). According to an embodiment, the switch 634 may switch to the first terminal S1 or the second terminal S2 to connect the PA 633 and the first duplexer 635 or connect the transceiver 631 and the first duplexer 635. For example, the switch 634 may switch to the first terminal S1 of the switch 634 to connect the PA 633 and the first duplexer 635 when the first transmission signal PTx1, the second transmission signal PTx2, or the signal PTx_{—merge} is ready to be transmitted through the first antenna ANT1. The switch 634 may switch to the second terminal S2 of the switch 634 to connect the transceiver 631 and the first duplexer 635 when the second reception signal PRx2 is received.

According to an embodiment, the switch 634 may include a Single-Pole Double Throw (SPDT) switch, a Single-Pole x Throw (SPxT) switch, and a Double-Pole x Throw (DPxT) switch.

According to an embodiment, the first antenna ANT1 is the main antenna of the electronic device and may transmit the first transmission signal PTx1, the second transmission signal PTx2, or the signal PTx_{—merge}. The first antenna ANT1 may also receive the first reception signal PRx1 corresponding to the reception band of the first communication scheme or the second reception signal PRx2 of the second communication scheme. As described above, the second reception signal PRx2 may correspond to the second band, which is one of the transmission bands of the first communication scheme.

According to an embodiment, the first duplexer 635 may separate wireless signals transmitted and received through the first antenna ANT1 into a signal corresponding to the transmission band of the first communication scheme and a signal corresponding to the reception band of the first communication scheme.

According to an embodiment, the first duplexer 635 may separate the wireless signals using a Time Division Duplexer (TDD).

According to an embodiment, the first duplexer 635 may include a first terminal D11 electrically connected to the first antenna ANT 1, a second terminal D12 electrically connected to the third terminal S3 of the switch 634, and a third terminal D13 electrically connected to the fourth port T4 of the transceiver 631.

According to an embodiment, the power controller 636 may control the operation voltage of the PA 633. According to an embodiment, the power controller 636 may control the operation voltage of the PA 633 on the basis of a predetermined fixed voltage (for example, a first fixed voltage or a second fixed voltage corresponding to a maximum output voltage of the first transmission signal PTx1 or the second transmission signal PTx2). According to an embodiment, the power controller 636 may control the operation voltage of the PA 633 on the basis of a predetermined adaptive voltage corresponding to a plurality of predetermined threshold voltages (for example, a first adaptive voltage or a second adaptive voltage corresponding to an output voltage of the first transmission signal PTx1 or the second transmission signal PTx2. The first adaptive voltage or the second adaptive voltage may be in the form of a stepwise signal and be based on the plurality of predetermined threshold voltages). FIG. 6 illustrates that the power controller 636 is separated from the processor 620, but that is only one example. In another example, and the power controller 636 may be included in the processor 620 or the processor 620 may perform the operation of the power controller 636 instead of the power controller 636. Accordingly, a detailed description of the power controller 636 will be replaced with the following description for the processor 620.

According to an embodiment, the processor 620 may overall control the communication circuit 630. According to an embodiment, the processor 620 may merge the first transmission signal PTx1 of the first communication scheme and the second transmission signal PTx2 of the second communication scheme using the communication circuit 630. According to an embodiment, the processor 620 may generate the first baseband transmission signal PTx1_{—BB} including a data packet of the first communication scheme and the second baseband transmission signal PTx2_{—BB} including a data packet of the second communication scheme and output the generated baseband transmission signal to the transceiver 631. According to an embodiment, using the transceiver 631, the processor 620 may amplify the first baseband transmission signal PTx1_{—BB} and/or the second baseband transmission signal PTx2_{—BB} and convert the amplified first baseband transmission signal and/or the amplified second baseband transmission signal into a wireless signal of the first transmission signal PTx1 or a wireless signal of the second transmission signal PTx2. According to an embodiment, the processor 620 may merge the first transmission signal PTx1 and the second transmission signal PTx2 into the signal

PTx1_PTx2=PTx_{—merge} using the first merger 632.

According to an embodiment, the processor 620 may amplify the first transmission signal PTx1, the second transmission signal PTx2, and/or the signal PTx_{—merge} using the power amplifier (for example, the PA 633) included in the communication circuit 630.

According to an embodiment, the processor 620 may control the operation of the PA 633 by applying voltage or power generated through various methods to the PA 633. For ease of description, the present disclosure describes that voltages generated through various methods are applied to the PA 633. However, the methods of the present disclosure can also apply to the power applied to the PA 633.

According to an embodiment, the processor 620 may amplify the first transmission signal PTx1, the second transmission signal PTx2, or the signal PTx_{—merge} using the PA 633 that operates based on a predetermined fixed voltage.

According to an embodiment, the processor 620 may control the operation voltage of the PA 633 such that the first transmission signal PTx1, the second transmission signal PTx2, or the signal PTx_{—merge} is amplified on the basis of a first fixed voltage or a second fixed voltage. The first fixed voltage may correspond to the maximum output voltage of the first transmission signal PTx1, and the second fixed voltage may correspond to the maximum output voltage of the second transmission signal PTx2. The processor 620 may generate the first fixed voltage (for example, V_{cc1}) corresponding to the maximum output voltage of the first transmission signal PTx1 and the second fixed voltage (for example, V_{cc2}) corresponding to the maximum output voltage of the second transmission signal PTx2. According to an embodiment, the first fixed voltage V_{cc1} may be higher than or equal to the maximum output voltage of the first transmission signal PTx1, and the second fixed voltage V_{cc2} may be higher than or equal to the maximum output voltage of the second transmission signal PTx2.

According to an embodiment, the processor 620 may amplify the first transmission signal PTx1, the second transmission signal PTx2, or the signal PTx_{—merge} using the PA 633 that operates on the basis of the generated first fixed voltage V_{cc1} or second fixed voltage V_{cc2}. For example, the processor 620 may configure the generated first fixed voltage V_{cc1} or second fixed voltage V_{cc2} as the operation voltage of the PA 633. The processor 620 may operate the PA 633 by applying the first fixed voltage V_{cc1} or second fixed voltage V_{cc2} as the operation voltage of the PA 633. The processor 620 may amplify the first transmission signal PTx1, the second transmission signal PTx2, or the signal PTx_{—merge} using the PA 633 which is operating according to the first fixed voltage V_{cc1} or second fixed voltage V_{cc2}.

According to an embodiment, the processor 620 may select the higher voltage between the first fixed voltage V_{cc1} and second fixed voltage V_{cc2} and configure the selected fixed voltage as the operation voltage of the PA 633. In another embodiment, the processor 620 may select the lower voltage between the first fixed voltage V_{cc1} and second fixed voltage V_{cc2} and configure the selected fixed voltage as the operation voltage of the PA 633. The processor 620 may then operate the PA 633 by applying the selected fixed voltage to amplify the first transmission signal PTx1, the second transmission signal PTx2, or the signal PTx_{—merge}. According to another embodiment, the processor 620 may amplify the first transmission signal PTx1, the second transmission signal PTx2, or the signal PTx_{—merge} using the PA 633 that is operating on the basis of a predetermined adaptive voltage.

According to an embodiment, the processor 620 may generate a first adaptive voltage V_{ad1} adaptively corresponding to the output voltage of the first transmission signal PTx1. The first adaptive voltage may be in the form of a stepwise signal and be based on a plurality of predetermined first threshold voltages. The processor 620 may configure in advance the plurality of first threshold voltages having a plurality of voltage levels of the first transmission signal PTx1. The first adaptive voltage V_{ad1} may be stored in the memory (for example, the memory 130) of the electronic device 501 as a table.

According to an embodiment, the processor 620 may generate a second adaptive voltage V_{ad2} adaptively corresponding to the output voltage of the second transmission signal PTx2. The second adaptive voltage may be in the form of a stepwise signal and be based on a plurality of predetermined second threshold voltages. The processor 620 may configure in advance the plurality of second threshold voltages having a plurality of voltage levels of the second transmission signal PTx2. The second adaptive voltage V_{ad2} may be stored in the memory (for example, the memory 130) of the electronic device 501 as a table.

According to an embodiment, the processor 620 may amplify the first transmission signal PTx1, the second transmission signal PTx2, or the signal PTx_{—merge} using the PA 633 which is operating on the basis of the generated first adaptive voltage V_{ad1} and/or second adaptive voltage V_{ad2}. For example, the processor 620 may configure the generated first adaptive voltage V_{ad1} as the operation voltage of the PA 633. The processor 620 may operate the PA 633 by applying the first adaptive voltage V_{ad1} to the PA 633. The processor 620 may amplify the first transmission signal PTx1, the second transmission signal PTx2, or the signal PTx_{—merge} using the PA 633 which is operating according to the first adaptive voltage V_{ad1}. In another example, the processor 620 may configure the generated second adaptive voltage V_{ad2} as the operation voltage of the PA 633. The processor 620 may operate the PA 633 by applying the second adaptive voltage V_{ad2} to the PA 633. The processor 620 may amplify the first transmission signal PTx1, the second transmission signal PTx2, or the signal PTx_{—merge} using the PA 633 which is operating according to the second adaptive voltage V_{ad2}.

According to an embodiment, the processor 620 may select an adaptive voltage between the generated first adaptive voltage V_{ad1} and second adaptive voltage V_{ad2}, depending on a predetermined condition, and amplify the first transmission signal PTx1, the second transmission signal PTx2, or the signal PTx_{—merge}.

According to an embodiment, the processor 620 may compare the first table storing the first adaptive voltage V_{ad1} and the second table storing the second adaptive voltage V_{ad2} and select an adaptive voltage between the first adaptive voltage V_{ad1} and the second adaptive voltage V_{ad2}, depending on the predetermined condition. According to an embodiment, the processor 620 may compare all of the first table and the second table and select a higher adaptive voltage between the first adaptive voltage V_{ad1} and the second adaptive voltage V_{ad2}. According to an embodiment, the processor 620 may compare all of the first table and the second table and select a lower adaptive voltage between the first adaptive voltage V_{ad1} and the second adaptive voltage V_{ad2}. According to an embodiment, the processor 620 may compare the first table and the second table according to each threshold voltage and select a higher adaptive voltage between the first adaptive voltage V_{ad1} and the second adaptive voltage V_{ad2}. According to an embodiment, the processor 620 may compare the first table and the second table according to each threshold voltage and select a lower adaptive voltage between the first adaptive voltage V_{ad1} and the second adaptive voltage V_{ad2}. According to an embodiment, the processor 620 may compare the first table and the second table according to each threshold voltage and select an adaptive voltage at each threshold voltage depending on different selection references. For example, the processor 620 may select a higher adaptive voltage between the first adaptive voltage V_{ad1} and the second adaptive voltage V_{ad2} corresponding to a first threshold voltage and select a lower adaptive voltage between the first adaptive voltage V_{ad1} and the second adaptive voltage V_{ad2} corresponding to a second threshold voltage.

According to an embodiment, the plurality of first threshold voltages and the plurality of second threshold voltages may be configured to be the same as each other. According to an embodiment, the plurality of first threshold voltages and the plurality of second threshold voltages may be configured to be different from each other.

According to an embodiment, the processor 620 may configure the selected adaptive voltage as the operation voltage of the PA 633. The processor 620 may operate the PA 633 by applying the selected adaptive voltage to the PA 633. The processor 620 may then amplify the first transmission signal PTx1, the second transmission signal PTx2, or the signal PTx_{—merge} using the PA 633 that is operating according to the selected adaptive voltage.

According to an embodiment, the processor 620 may generate a third table corresponding to the selected adaptive voltage. The generated third table may be stored in the memory (for example, the memory 130).

According to an embodiment, the processor 620 may acquire a third adaptive voltage on the basis of the first adaptive voltage V_{ad1} or the second adaptive voltage V_{ad2} and amplify the first transmission signal PTx1, the second transmission signal PTx2, or the signal PTx_{—merge} using the PA 633 that is operating on the basis of the acquired third adaptive voltage.

According to an embodiment, the processor 620 may acquire intermediate values between the generated first adaptive voltage V_{ad1} and second adaptive voltage V_{ad2} as the third adaptive voltage. For example, the processor 620 may acquire the intermediate values between the generated first adaptive voltage V_{ad1} and second adaptive voltage V_{ad2} using the first table storing the first adaptive voltage V_{ad1} and the second table storing the second adaptive voltage V_{ad2}. The processor 620 may amplify the first transmission signal PTx1, the second transmission signal PTx2, or the signal PTx_{—merge} using the PA 633 that is operating on the basis of the acquired third adaptive voltage. For example, the processor 620 may configure the acquired third adaptive voltage as the operation voltage of the PA 633. The processor 620 may operate the PA 633 by applying the acquired third adaptive voltage to the PA 633. The processor 620 may then amplify the first transmission signal PTx1, the second transmission signal PTx2, or the signal PTx_{—merge} using the PA 633 that is operating according to the acquired intermediate values.

According to an embodiment, the processor 620 may acquire, as the third adaptive voltage, voltages obtained by applying a predetermined weighted value to at least one of the first adaptive voltage V_{ad1} and the second adaptive voltage V_{ad2} or according to a predetermined equation. The processor 620 may amplify the first transmission signal PTx1, the second transmission signal PTx2, or the signal PTx_{—merge} using the PA 633 that is operating on the basis of the acquired third adaptive voltage. For example, the weighted value or the equation may be determined by the user or configured in advance in the electronic device 501. According to an embodiment, the equation may include various equations using at least one of the first adaptive voltage V_{ad1} and the second adaptive voltage V_{ad2}. The processor 620 may configure the acquired third adaptive voltage as the operation voltage of the PA 633. The processor 620 may operate the PA 633 by applying the third adaptive voltage to the PA 633. For example, the processor 620 may amplify the first transmission signal PTx1, the second transmission signal PTx2, or the signal PTx_{—merge} using the PA 633 that is operating according to the acquired third adaptive voltages.

According to an embodiment, the processor 620 may amplify the first transmission signal PTx1, the second transmission signal PTx2, or the signal PTx_{—merge} using the PA 633 that is operating on the basis of a predetermined envelope voltage V_{E}. A method of controlling the PA 633 on the basis of the envelope voltage V_{E} will be described below in more detail with reference to FIG. 6C.

Referring to FIG. 6B, the communication circuit 630 operationally connected to the processor 620 of the electronic device (for example, the electronic device 501) according to an embodiment may include at least one of the transceiver 631, the first merger 632, the PA 633, the switch 634, the first duplexer 635, the first antenna ANT1, and the power controller 636. Since the configuration of FIG. 6B is the same as that of FIG. 6A except for the location of the switch 634, descriptions of the same elements will be omitted.

According to an embodiment, the switch 634 may be disposed between the first duplexer 635 and the first antenna ANT1 as illustrated in FIG. 6B. In this case, the first terminal D11 of the first duplexer 635 may be electrically connected to the first terminal 51 of the switch 634, the second terminal D12 of the first duplexer 635 may be electrically connected to the output terminal P2 of the PA 633, and the third terminal D13 of the first duplexer 635 may be connected to the third port T3 of the transceiver 631.

According to an embodiment, the switch 634 may include the first terminal 51 electrically connected to the first terminal D11 of the first duplexer 635, the second terminal S2 electrically connected to the fourth port T4 of the transceiver 631, and the third terminal S3 electrically connected to the first antenna ANT1. According to an embodiment, the switch 634 may switch to the first terminal 51 to connect the first duplexer 635 and the first antenna ANT 1. Alternatively, the switch 634 may switch to the second terminal S2 to connect the transceiver 631 and the first antenna ANT1. For example, the switch 634 may switch to the first terminal 51 of the switch 634 to connect the first duplexer 635 and the first antenna ANT1 when the first transmission signal PTx1, the second transmission signal PTx2, or the signal PTx_{—merge} is to be transmitted through the first antenna ANT1 or when the first reception signal PRx1 is received through the first antenna ANT1. The switch 634 may switch to the second terminal S2 of the switch 634 to connect the transceiver 631 and the first antenna ANT1 when the second reception signal PRx2 is received through the first antenna ANT1.

Referring to FIG. 6C, the communication circuit 630 operationally connected to the processor 620 of the electronic device according to an embodiment may include at least one of the transceiver 631, the first merger 632, a second merger 637, the PA 633, the switch 634, the first duplexer 635, the first antenna ANT1, and the power controller 636. Since the configuration of FIG. 6C is the same as that of FIG. 6A except for the second merger 637, descriptions of the same elements will be omitted.

According to an embodiment, the second merger 637 may merge the first baseband transmission signal PTx1_{—BB} and the second baseband transmission signal PTx2_{—BB} provided from the processor 620. The second merger 637 may output the merged baseband transmission signal (for example, PTx1_{—BB} PTx2_{—BB}=PTx_{—BB merge}).

According to an embodiment, the processor 620 may generate the first baseband transmission signal PTx1_{—BB} corresponding to first transmission data when an input for transmitting the first transmission data related to a first application (for example, a broadcast-related application or a data transmission/reception application) is received. The first application may communicate through the first communication scheme using the first band that is one of the plurality of transmission bands of the first communication scheme.

According to an embodiment, the processor 620 may generate the second baseband transmission signal PTx2_{—BB} corresponding to second transmission data when an input for transmitting the second transmission data related to a second application (for example, a message exchange application, a content exchange application, or a voice exchange application) is received. The second application may communicate through the second communication scheme using the second band that is one of the plurality of transmission bands of the first communication scheme.

According to an embodiment, the second merger 637 may include a first input terminal C21 electrically connected to the processor 620, a second input terminal C22 electrically connected to the processor 620, and an output terminal C23 for outputting the baseband transmission signal PTx_{—BB merge} obtained by merging the first baseband transmission signal PTx1_{—BB} and the second baseband transmission signal PTx2_{—BB}.

According to an embodiment, the power controller 636 may control the operation voltage of the PA 633 on the basis of the output voltage of the first baseband transmission signal PTx1_{—BB}, the second baseband transmission signal PTx2_{—BB}, and/or the merged transmission signal PTx_{—BB merge}. For example, the power controller 636 may control the operation voltage of the PA 633 on the basis of an envelope voltage (for example, V_{E}) corresponding to the output voltage of the baseband transmission signal PTx_{—BB merge}. FIG. 6C illustrates that the power controller 636 is separated from the processor 620, but that is only one example. In another example, the power controller 636 may be included in the processor 620 or the processor 620 may perform the operation of the power controller 636 instead of the power controller 636. Accordingly, a detailed description of the power controller 636 will be replaced with the following description for the processor 620.

According to an embodiment, the processor 620 may control the operation voltage of the PA 633 to amplify the signal PTx_{—merge} on the basis of the envelope voltage V_{E} corresponding to the output voltage of the baseband transmission signal PTx_{—BB merge}.

According to an embodiment, the processor 620 may merge the first baseband transmission signal PTx1_{—BB} and the second baseband transmission signal PTx2_{—BB} using the second merger 637. For example, the processor 620 may generate the merged baseband transmission signal PTx_{—BB merge} by summing the output voltage of the first baseband transmission signal PTx1_{—BB} and the output voltage of the second baseband transmission signal PTx2_{—BB}. The processor 620 may generate the envelope voltage V_{E} corresponding to the output voltage of the merged baseband transmission signal PTx_{—BB merge}. For example, the processor 620 may generate the envelope voltage V_{E} such that the merged baseband transmission signal PTx_{—BB merge} and the envelope voltage V_{E} have a predetermined voltage width (for example, margin) therebetween.

According to an embodiment, the processor 620 may amplify the first transmission signal PTx1, the second transmission signal PTx2, or the signal PTx_{—merge} using the PA 633 that is operating on the basis of the generated envelope voltage V_{E}. For example, the processor 620 may configure the generated envelope voltage V_{E} as the operation voltage of the PA 633. The processor 620 may perform controls to operate the PA 633 by applying the generated envelope voltage V_{E} to the PA 633. The processor 620 may then amplify the first transmission signal PTx1, the second transmission signal PTx2, or the merged signal PTx_{—merge} using the PA 633 that is operating according to the generated envelope voltage V_{E}.

Referring to FIG. 6D, the communication circuit 630 operationally connected to the processor 620 of the electronic device (for example, the electronic device 501) according to an embodiment may include at least one of the transceiver 631, the PA 633, the switch 634, the first duplexer 635, the first antenna ANT1, and the power controller 636. Since the configuration of FIG. 6D is the same as that of FIG. 6C except that the first merger 632 is integrated into the transceiver 631 and the second merger 637 is integrated into the processor 620, descriptions of the same elements will be omitted.

According to an embodiment, the processor 620 may generate the first baseband transmission signal (for example, PTx1_{—BB}) of the first communication scheme. The processor 620 may generate the second baseband transmission signal (for example, PTx2_{—BB}) of the second communication scheme. The processor 620 may generate the baseband transmission signal (for example, PTx_{—BB merge}) by merging the first baseband transmission signal PTx1_{—BB} and the second baseband transmission signal PTx2_{—BB}.

According to an embodiment, the processor 620 may provide the first baseband transmission signal PTx1_{—BB}, the second baseband transmission signal PTx2_{—BB}, or the merged baseband transmission signal PTx_{—BB merge} to at least one of the transceiver 631 and the power controller 636.

According to an embodiment, the transceiver 631 may convert the first baseband transmission signal PTx1_{—BB}, the second baseband transmission signal PTx2_{—BB}, or the merged baseband transmission signal PTx_{—BB merge} provided from the processor 620 into a wireless signal. In addition, the transceiver may convert a wireless signal received through the first antenna ANT1 into a baseband reception signal (not shown). For example, the transceiver 631 may generate the first transmission signal PTx1 (not shown), which is a converted wireless signal, in part by amplifying the first baseband transmission signal PTx1_{—BB} provided from the processor 620. The transceiver 631 may generate the second transmission signal PTx2, which is another wireless signal, in part by amplifying the second baseband transmission signal PTx2_{—BB} provided from the processor 620. The transceiver 631 may generate the signal PTx_{—merge}, which is yet another wireless signal, in part by amplifying signal PTx_{—BB merge} provided from the processor 620. According to an embodiment, the transceiver 631 may generate the first transmission signal PTx1 or generate the second transmission signal PTx2 on the basis of the merged baseband transmission signal PTx_{—BB merge} provided from the processor 620.

According to an embodiment, the transceiver 631 may merge the first transmission signal PTx1 and the second transmission signal PTx2. According to an embodiment, the transceiver 631 may provide the PA 633 with at least one of the first transmission signal PTx1, the second transmission signal PTx2, and the signal PTx_{—merge}.

According to an embodiment, the transceiver 631 may include a first port T11 (for example, which may serve the functions of the first port T1 and the second port T2 of FIG. 6C), which is electrically connected to the input terminal P1 of the PA 633 to transmit one of the first transmission signal PTx1, the second transmission signal PTx2, and the signal PTx_{—merge}. The transceiver 631 may further included a second port T12 (for example, a port corresponding to the third port T3 of FIG. 6C) for receiving the second reception signal PRx2, and a third port T13 (for example, a port corresponding to the fourth port T4 of FIG. 6C) for receiving the first reception signal PRx1.

Referring to FIG. 6E, the communication circuit 630 operationally connected to the processor 620 of the electronic device (for example, the electronic device 501) according to an embodiment may include at least one of the transceiver 631, the first merger 632, the PA 633, the switch 634, the first duplexer 635, the first antenna ANT1, the power controller 636, a second antenna ANT2, and a second duplexer 638. Since the configuration of FIG. 6E is the same as that of FIG. 6A except for the second antenna ANT 2 and the second duplexer 638, descriptions of the same elements will be omitted.

According to an embodiment, the second antenna ANT2 is an auxiliary antenna and may receive a third reception signal (for example, DRx1) of the first communication scheme corresponding to the reception bands of the first communication scheme or a fourth reception signal (for example, DRx2) of the second communication scheme corresponding to the second band that is one of the transmission bands of the first communication scheme.

According to an embodiment, the third reception signal DRx1 may include LTE DL reception data corresponding to LTE DL bands. According to an embodiment, the fourth reception signal DRx2 may include LTE D2D reception data corresponding to the second band in the LTE UL bands.

According to an embodiment, the transceiver 631 may further include a fifth port T5 for receiving the third reception signal DRx1 and a sixth port T6 for receiving the fourth signal DRx2.

According to an embodiment, the second duplexer 638 may separate wireless signals received through the second antenna ANT2 into a signal corresponding to the second band in the transmission bands of the first communication scheme and a signal corresponding to the reception bands of the first communication scheme.

According to an embodiment, the second duplexer 638 may separate the wireless signals using TDD.

According to an embodiment, the second duplexer 638 may include a first terminal D21 electrically connected to the second antenna ANT2, a second terminal D22 electrically connected to the fifth port T5 of the transceiver 631, and a third terminal D23 electrically connected to the sixth port T6 of the transceiver 631.

According to an embodiment, the processor 620 may convert the third reception signal DRx1 or the fourth reception signal DRx2, which are wireless signals received through the second antenna ANT2, into a third baseband reception signal (not shown) or a fourth baseband reception signal (not shown) using the transceiver 631. The processor 620 may transfer, to the processor 620, the third baseband reception signal or the fourth baseband reception signal. The processor 620 may transfer the third baseband reception signal or the fourth baseband reception signal to an application processor (for example, the first processor 510, also not shown). The application processor (for example, the first processor 510) may decode data included in the third baseband reception signal or the fourth baseband reception signal to recover, for example, image signals or voice signals. The application processor (for example, the first processor 510) may store the recovered data in the memory (for example, the memory 130) or display the recovered data on the display (for example, the display 160).

According to an embodiment, the electronic device (for example, the electronic device 501) may include the communication circuit (for example, the communication circuit 630) and the processor (for example, the processor 620) operationally connected to the communication circuit 630. The processor 620 may be configured to use the communication circuit to merge the first transmission signal of the first communication scheme corresponding to the first band that is one of transmission bands of the first communication scheme and the second transmission signal of the second communication scheme corresponding to the second band that is one of the transmission bands, amplify the merged first transmission signal and second transmission signal using the PA (for example, the PA 633), transmit the amplified first transmission signal to a first external electronic device communicating in the first communication scheme, and transmit the amplified second transmission signal to a second external electronic device communicating in the second communication scheme.

According to an embodiment, the first communication scheme may be a cellular communication network scheme, and the second communication scheme may be a D2D communication scheme based on cellular communication.

According to an embodiment, the communication circuit 630 may include the transceiver (for example, the transceiver 631) for converting the first baseband transmission signal of the first communication scheme corresponding to the first transmission signal and the second baseband transmission signal of the second communication scheme corresponding to the second transmission signal into the first transmission signal and the second transmission signal, the first merger for merging the first transmission signal and second transmission signal, and the PA 633 for amplifying the merged first transmission signal and second transmission signal.

According to an embodiment, the communication circuit 630 may further include the first antenna (for example, the first antenna ANT1) configured to transmit the merged first transmission signal and second transmission signal, receive the first reception signal of the first communication scheme corresponding to reception bands of the first communication scheme, and/or receive the second reception signal of the second communication scheme corresponding to the second band of the first communication scheme, the first duplexer (for example, the first duplexer 635) for separating signals transmitted or received through the first antenna ANT1 into a signal corresponding to the transmission bands of the first communication scheme and a signal corresponding to the reception bands of the first communication scheme, and the switch (for example, the switch 634) for connecting the PA 633 and the first duplexer 635 to transmit the second transmission signal or connecting the transceiver 631 and the first duplexer 635 to receive the second reception signal.

According to an embodiment, the processor 620 may be configured to generate the first fixed voltage corresponding to a maximum output voltage of the first transmission signal or the second fixed voltage corresponding to a maximum output voltage of the second transmission signal, and amplifying the merged first transmission signal and second transmission signal using the PA that is operating based on the generated first fixed voltage or second fixed voltage.

According to an embodiment, the processor 620 may be configured to generate the first adaptive voltage adaptively corresponding to the output voltage of the first transmission signal, the first adaptive voltage being in the form of a stepwise signal and is generated based on a plurality of predetermined first threshold voltages, and amplify the merged first transmission signal and second transmission signal using the PA that is operating based on the generated first adaptive voltage.

According to an embodiment, the processor 620 may be configured to generate the second adaptive voltage adaptively corresponding to the output voltage of the second transmission signal, the second adaptive voltage being in the form of a stepwise signal and is generated based on a plurality of predetermined second threshold voltages, and amplify the merged first transmission signal and second transmission signal using the PA that is operating based on the generated second adaptive voltage.

According to an embodiment, the processor 620 may be configured to generate the first adaptive voltage corresponding to the output voltage of the first transmission signal, the first adaptive voltage being in the form of a stepwise signal and is generated based on a plurality of predetermined first threshold voltages, generate the second adaptive voltage adaptively corresponding to the output voltage of the second transmission signal, the second adaptive voltage being in the form of a stepwise signal and is generated based on a plurality of predetermined second threshold voltages, select an adaptive voltage between the first adaptive voltage and the second adaptive voltage based on a predetermined condition, and amplify the merged first transmission signal and second transmission signal using the PA that is operating based on the selected adaptive voltage.

According to an embodiment, the processor 620 may be configured to generate the first adaptive voltage adaptively corresponding to the output voltage of the first transmission signal, the first adaptive voltage being in the form of a stepwise signal and is generated based on a plurality of predetermined first threshold voltages, generate the second adaptive voltage adaptively corresponding to the output voltage of the second transmission signal, the second adaptive voltage being in the form of a stepwise signal and is generated based on a plurality of predetermined second threshold voltages, acquire a third adaptive voltage based on the first adaptive voltage or the second adaptive voltage, and amplify the merged first transmission signal and second transmission signal using the PA that is operating based on the acquired third adaptive voltage.

According to an embodiment, the processor 620 may further include a second merger 637 for merging the first baseband transmission signal and the second baseband transmission signal.

According to an embodiment, the processor 620 may be configured to merge the first baseband transmission signal and the second baseband transmission signal, generate an envelope voltage corresponding to an output voltage of the merged baseband transmission signal, and amplify the merged first transmission signal and second transmission signal using the PA that is operating based on the generated envelope voltage.

According to an embodiment, the communication circuit 630 may further include the second antenna ANT2 for receiving a third reception signal of the first communication scheme corresponding to the reception bands of the first communication scheme or a fourth reception signal of the second communication scheme corresponding to the second band of the first communication scheme and the second duplexer 638 for separating signals received through the second antenna ANT2 into a signal corresponding to the second band and a signal corresponding to the reception bands.

According to an embodiment, the electronic device (for example, the electronic device 501) may include a housing (not shown), an antenna unit (for example, the first antenna ANT1) at least partially disposed inside or on the housing (not shown), at least one transceiver circuit (for example, the transceiver 631) including a first port T1, a second port T2, a third port T3, and a fourth port T4, a first merger (for example, the first merger 632) including a first input terminal C11 electrically connected to the first port T1, a second input terminal C12 electrically connected to the second port T2, and an output terminal C13, a PA (for example, the PA 633) including an input terminal P1 electrically connected to the output terminal C13 of a first merger (for example, the first merger 632) and an output terminal P2, and a switching unit (for example, the switch 634) including a first terminal Si electrically connected to the output terminal P2 of the PA 633, a second terminal S2 electrically connected to the third port T3, and a third terminal S3 electrically connected to the antenna unit ANT1. The fourth port T4 may be electrically connected to the antenna unit ANT1 without being electrically connected to the first merger 632, the PA 633, and the switching unit 634. The transceiver circuit 631 may be configured to transmit Long-Term Evolution (LTE) UpLink (UL) transmission data corresponding to a first band that is one of LTE UL bands through the first port T1, transmit LTE Device-to-Device (D2D) transmission data corresponding to a second band that is one of the LTE UL bands through the second port T2, receive LTE D2D reception data corresponding to the second band through the third port T3, and receive LTE DownLink (DL) reception data corresponding to LTE DL bands through the fourth port T4.

According to an embodiment, the electronic device 501 may further include a duplexer (for example, the first duplexer 635) including a first terminal D11 electrically connected to the antenna unit ANT1, a second terminal D12 electrically connected to the third terminal S3 of the switching unit 634, and a third terminal D13 electrically connected to the fourth port T4. The duplexer 635 may be configured to separate data transmitted or received through the antenna unit ANT1 into data corresponding to the LTE UL bands and data corresponding to the LTE DL bands.

According to an embodiment, the duplexer 635 may separate the data using a time division duplex scheme.

According to an embodiment, the switching unit 634 may be configured to switch to the first terminal S1 of the switching unit 634 to connect the PA 633 and the duplexer 635 when the LTE UL transmission data, the LTE D2D transmission data, or the LTE UL transmission data and the LTE D2D transmission data, which are merged through the first merger 632 is transmitted. The switching unit 634 may be configured to switch to the second terminal S2 of the switching unit 634 to connect the transceiver 631 and the duplexer 635 when the LTE D2D reception data is received.

According to an embodiment, the electronic device 501 may further include at least one processor (for example, the processor 620) for controlling the antenna unit ANT1, the transceiver circuit 631, the first merger 632, the PA 633, and the switching unit 634, a second merger (for example, the second merger 637) including a first input terminal C21 electrically connected to the processor 620, a second input terminal C22 electrically connected to the processor 620, and an output terminal C23, and a power controller (for example, the power controller 636) for controlling an operation of the PA 633 on the basis of an envelope voltage corresponding to an output voltage of baseband transmission data obtained by using the second merger 637 to merge LTE UL baseband transmission data corresponding to the LTE UL transmission data and LTE D2D baseband transmission data corresponding to the LTE D2D transmission data.

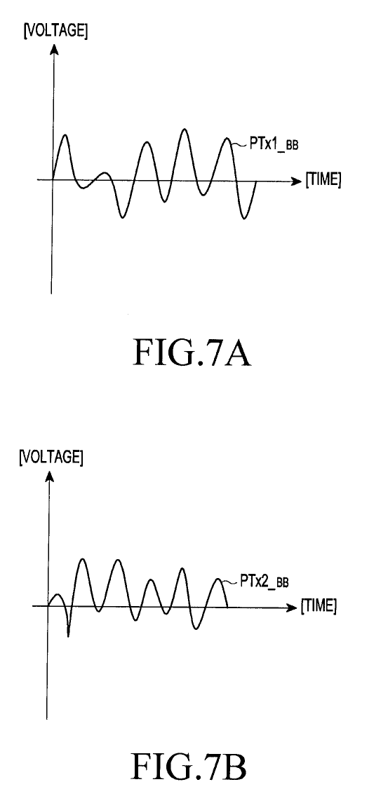

FIG. 7A illustrates an example of the first baseband transmission signal of the first communication scheme according to an embodiment, and FIG. 7B illustrates an example of the second baseband transmission signal of the second communication scheme according to an embodiment. FIGS. 7A and 7B illustrate the baseband transmission signals in the time domain, where output voltages of the baseband transmission signals fluctuate in time.

Referring to FIGS. 7A and 7B, the processor (for example, the processor 620) of the electronic device (for example, the electronic device 501) according to an embodiment may generate the first baseband transmission signal (for example, PTx1_{—BB}) of the first communication scheme and the second baseband transmission signal (for example, PTx2_{—BB}) of the second communication scheme. According to an embodiment, the output voltages of the first baseband transmission signal (for example, PTx1_{—BB}) and the second baseband transmission signal (for example, PTx2_{—BB}) fluctuate in time and may be different from each other. The processor 620 of the electronic device 501 may transfer the generated first baseband transmission signal PTx1_{—BB} and/or the second baseband transmission signal PTx2_{—BB} to at least one of the transceiver (for example, the transceiver 631), the second merger (for example, the second merger 637), and the power controller (for example, the power controller 636).

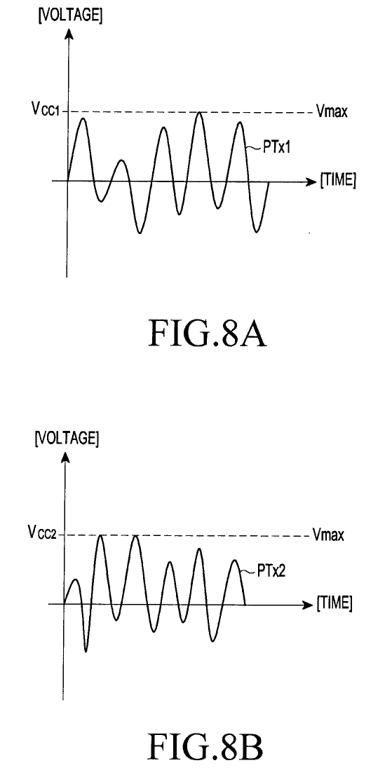

FIG. 8A illustrates an example of the first transmission signal of the first communication scheme corresponding to a first band, which is one of the transmission bands of the first communication scheme of the electronic device, according to an embodiment, and FIG. 8B illustrates an example of the second transmission signal of the second communication scheme corresponding to a second band, which is one of the transmission bands of the first communication scheme of the electronic device, according to an embodiment. FIGS. 8A and 8B illustrate the transmission signals in the time domain, where output voltages of the transmission signals fluctuate in time.

Referring to FIGS. 8A and 8B, the first transmission signal PTx1 of the first communication scheme corresponding to a first band in the transmission bands of the first communication scheme of the electronic device (for example, the electronic device 501) and the second transmission signal PTx2 of the second communication scheme corresponding to a second band in the transmission bands are illustrated. The first transmission signal PTx1 and the second transmission signal PTx2 are signals, which are generated by amplifying the first baseband transmission signal PTx1_{—BB} and the second baseband transmission signal PTx2 illustrated in FIGS. 7A and 7B by the transceiver (for example, the transceiver 631) of the electronic device 501 and converting the amplified signals into wireless signals. The converted first transmission signal PTx1, the converted second transmission signal PTx2, or the signal PTx_{—merge} obtained by merging the first transmission signal PTx1 and the second transmission signal PTx2 using the first merger (for example, the first merger 632) may be further amplified through the PA (for example, the PA 633) of the electronic device 501.

According to an embodiment, the processor (for example, the processor 620) of the electronic device 501 may generate a first fixed voltage V_{cc1} corresponding to the maximum output voltage Vmax of the first transmission signal PTx1 or a second fixed voltage V_{cc2} corresponding to the maximum output voltage Vmax of the second transmission signal PTx2. The first fixed voltage V_{cc1} may be higher than or equal to the maximum output voltage Vmax of the first transmission signal PTx1 and the second fixed voltage V_{cc2} may be higher than or equal to the maximum output voltage Vmax of the second transmission signal PTx2.

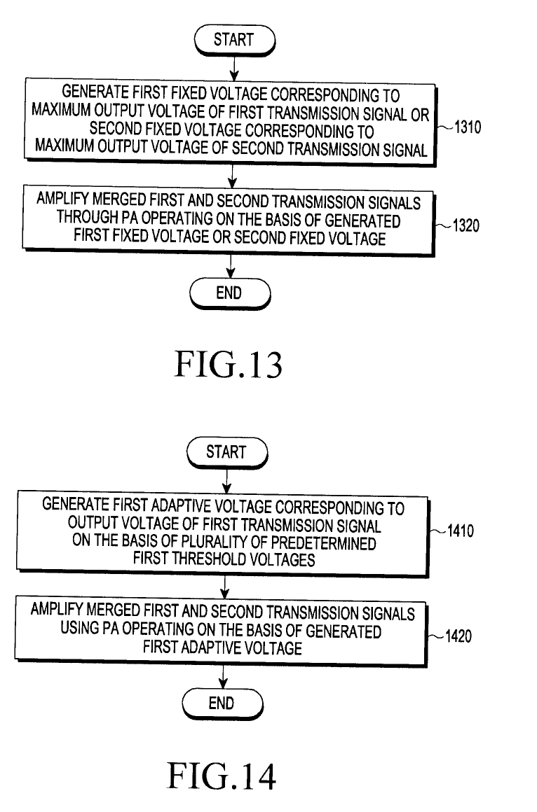

According to an embodiment, the processor 620 of the electronic device 501 may control the operation of the PA 633 by configuring the generated first fixed voltage V_{cc1} or second fixed voltage V_{cc2} as the operation voltage of the PA 633 of the electronic device 501. A method of controlling the operation of the PA 633 on the basis of the first fixed voltage V_{cc1} or the second fixed voltage V_{cc2} will be described below in more detail with reference to FIG. 13.

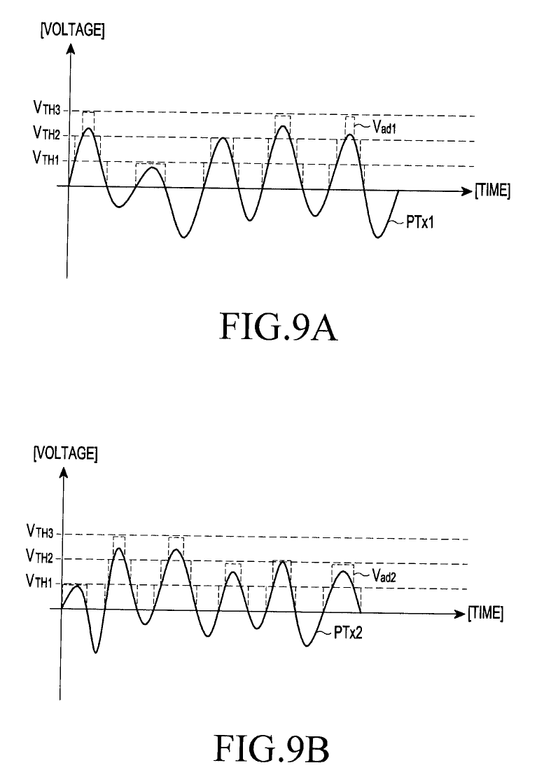

FIG. 9A illustrates an example of a first adaptive voltage corresponding to the first transmission signal of the first communication scheme, which in turn corresponds to a first band, which is one of the transmission bands of the first communication scheme of the electronic device, according to an embodiment, and FIG. 9B illustrates an example of a second adaptive voltage corresponding to the second transmission signal of the second communication scheme, which in turn corresponds to a second band, which is one of the transmission bands of the first communication scheme of the electronic device according to an embodiment. FIGS. 9A and 9B illustrate adaptive voltages corresponding to transmission signals, wherein the adaptive voltages correspond to fluctuations in time of the output voltages of the transmission signals.

Referring to FIGS. 9A and 9B, a first adaptive voltage (for example, V_{ad1}) corresponding to the first transmission signal PTx1 of the first communication scheme and a second adaptive voltage V_{ad2} corresponding to the second transmission signal PTx2 of the second communication scheme are illustrated.

The first adaptive voltage V_{ad1} may be a voltage that adaptively correspond to the output voltage of the first transmission signal PTx1. The first adaptive voltage V_{ad1} may be in the form of a stepwise signal and be based on a plurality of predetermined first threshold voltages V_{TH1} to V_{TH3}.

The second adaptive voltage V_{ad2} may be a voltage that adaptively correspond to the output voltage of the second transmission signal PTx2. The second adaptive voltage V_{ad2} may be in the form of a stepwise signal and be based on the plurality of predetermined second threshold voltages V_{TH1} to V_{TH3}. The second threshold voltages V_{TH1} to V_{TH3} may the same or different from the first threshold voltages V_{TH1} to V_{TH3}.

According to an embodiment, the electronic device (for example, the electronic device 501) may control the operation of the PA 633 by configuring the first adaptive voltage V_{ad1} as the operation voltage of the PA (for example, the PA 633) of the electronic device 501.

According to an embodiment, the electronic device 501 may control the operation of the PA 633 by configuring the second adaptive voltage V_{ad2} as the operation voltage of the PA (for example, the PA 633) of the electronic device 501.

According to an embodiment, the electronic device 501 may control the operation of the PA 633 by selecting an adaptive voltage between the first adaptive voltage V_{ad1} and the second adaptive voltage V_{ad2}, depending to a predetermined condition, and configuring the selected adaptive voltage as the operation voltage of the PA (for example, the PA 633) of the electronic device 501.

According to an embodiment, the electronic device 501 may control the operation of the PA 633 by calculating a third adaptive voltage based on the first adaptive voltage V_{ad1} and/or the second adaptive voltage V_{ad2} and configuring the calculated adaptive voltage as the operation voltage of the PA (for example, the PA 633) of the electronic device 501.

A method of controlling the operation of the PA 633 on the basis of the first adaptive voltage V_{ad1} or the second adaptive voltage V_{ad2} will be described below in more detail with reference to FIGS. 13 to 16.

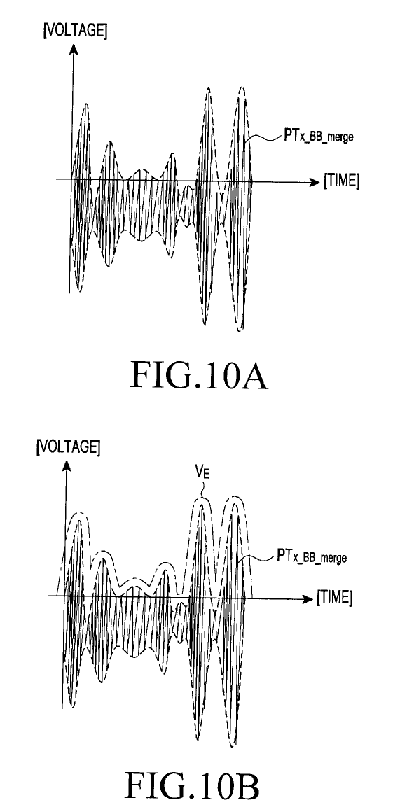

FIG. 10A illustrates an example of a baseband transmission signal obtained by merging the first baseband transmission signal of the first communication scheme and the second baseband transmission signal of the second communication scheme, according to an embodiment, and FIG. 10B illustrates an example of the envelope voltage corresponding to the output voltage of the merged baseband transmission signal according to an embodiment. FIG. 10A illustrates the merged baseband transmission signal in the time domain, where the output voltage of the merged baseband transmission signal fluctuates in time, and FIG. 10B illustrates the envelope voltage (for example, V_{E}) corresponding to the merged baseband transmission signal, wherein the envelope voltage corresponds to the fluctuations in time of the output voltage of the merged baseband transmission signal.

Referring to FIGS. 10A and 10B, the baseband transmission signal PTx_{—BB merge} obtained by merging the first baseband transmission signal PTx1_{—BB} of the first communication scheme and the second baseband transmission signal PTx2_{—BB} of the second communication scheme is illustrated. The merged baseband transmission signal PTx_{—BB merge} may merge the first baseband transmission signal PTx1_{—BB} and the second baseband transmission signal PTx2_{—BB} by using, for example, the second merger (for example, the second merger 637 of FIG. 6C) of the electronic device (for example, the electronic device 501) or the processor (for example, the processor 620 of FIG. 6D).

According to an embodiment, the electronic device 501 may generate the envelope voltage V_{E} corresponding to the output voltage of the merged baseband transmission signal PTx_{—BB merge}. The electronic device 501 may control the operation of the PA 633 by configuring the generated envelope voltage V_{E} as the operation voltage of the first PA (for example, the PA 633) of the electronic device 501.

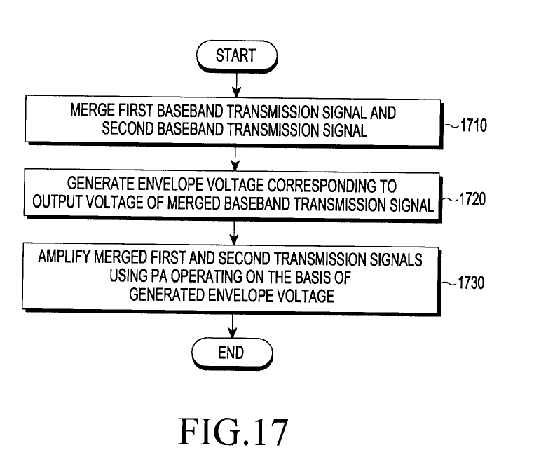

A method of controlling the operation of the PA 633 on the basis of the envelope voltage V_{E} will be described below in more detail with reference to FIG. 17.

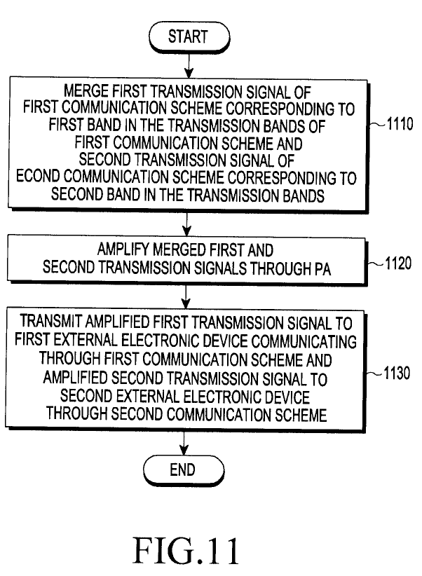

FIG. 11 is a flowchart illustrating a wireless communication method of the electronic device according to an embodiment. The wireless communication method shown in FIG. 11 may include operations 1110 to 1130. The wireless communication method shown in FIG. 11 may be performed by at least one of the electronic device (for example, the electronic device 501) or the processor (for example, the processor 620) of the electronic device.

In operation 1110, for example, the electronic device may merge the first transmission signal (for example, PTx1) of the first communication scheme corresponding to a first band in the transmission bands (for example, uplink bands of the cellular communication network) of the first communication scheme and the second transmission signal (for example, PTx2) of the second communication scheme corresponding to a second band in the transmission bands of the first communication scheme. The merge may be performed by the communication circuit (for example, the communication circuit 630) operationally connected to the processor (for example, the processor 620).

According to an embodiment, the electronic device may merge the first transmission signal and the second transmission signal using the first merger (for example, the first merger 632) within the communication circuit.

According to an embodiment, the first communication scheme is a communication scheme through the communication network, for example, a cellular communication network scheme. According to an embodiment, the cellular communication network scheme may include a Long-Term Evolution (LTE) or LTE-Advanced (LTE-A) communication network.

According to an embodiment, the second communication scheme is a D2D communication scheme and may include, for example, a cellular-based D2D communication scheme. According to an embodiment, the cellular-based D2D communication scheme may include Proximity based services (ProSe) or LTE D2D.

According to an embodiment, the transmission bands of the first communication scheme may be LTE UpLink (UL) bands.

According to an embodiment, the first transmission signal (PTx1) may include LTE UL transmission data corresponding to a first band in the LTE UL bands. According to an embodiment, the second transmission signal (PTx2) may include LTE D2D transmission data corresponding to a second band in the LTE UL bands.

In operation 1120, for example, the electronic device may amplify the merged first transmission signal and second transmission signal (for example, PTx1+PTx2=PTx_{—merge}) through one PA (for example, the PA 633).

According to an embodiment, the electronic device may control the PA to amplify the merged first transmission signal and second transmission signal on the basis of the first fixed voltage (for example, V_{cc1}) corresponding to the maximum output voltage of the first transmission signal and/or the second fixed voltage (for example, V_{cc2}) corresponding to the maximum output voltage of the second transmission signal.

According to an embodiment, the electronic device may control the PA to amplify the merged first transmission signal and second transmission signal on the basis of the first adaptive voltage (for example, V_{ad1}) corresponding to the output voltage of the first transmission signal and/or the second adaptive voltage (for example, V_{ad2}) corresponding to the output voltage of the second transmission signal. The first adaptive voltage may be in the form of a stepwise signal.

According to an embodiment, the electronic device may merge the first baseband transmission signal (for example, PTx1_{—BB}) of the first communication and the second baseband transmission signal (for example, PTx2_{—BB}) of the second communication scheme and control the PA to amplify the merged first transmission signal and second transmission signal on the basis of the envelope voltage (for example, V_{E}) corresponding to the merged baseband transmission signal (for example, PTx1_{—BB}+PTx2_{—BB}=PTx2_{—BB}_{_}_{merge}).

In operation 1130, for example, the electronic device may be configured to transmit the amplified first transmission signal to a first external electronic device communicating in the first communication scheme and to transmit the amplified second transmission signal to a second external electronic device communicating in the second communication scheme.

According to an embodiment, the electronic device may transmit the amplified first transmission signal to the first external electronic device through the cellular communication network and the amplified second transmission signal to the second external electronic device through cellular-based D2D communication.

According to an embodiment, the first external electronic device may be the BS (for example, the BS 400 or 450) of the cellular communication network, the server (for example, the server 106) of the BS, or another electronic device (for example, the electronic device 104) connected through the BS or the server.

According to an embodiment, the second external electronic device may be another electronic device (for example, the electronic device 102 or the electronic device 402-1 or 402-2), which is adjacent to the electronic device (for example, the electronic device 501) and performs cellular-based D2D communication with the electronic device (for example, the electronic device 501).

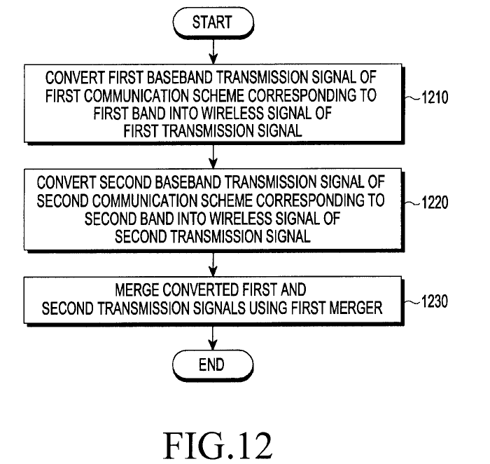

FIG. 12 is a flowchart illustrating a wireless communication method of the electronic device according to an embodiment. The wireless communication method shown in FIG. 12 may illustrate the transmission signal merging method in operation 1110 of FIG. 11 and may include operations 1210 to 1230. The wireless communication method shown in FIG. 12 may be performed by at least one of the electronic device (for example, the electronic device 501) or the processor (for example, the processor 620) of the electronic device.

In operation 1210, for example, the electronic device may convert the first baseband transmission signal (for example, PTx1_{—BB}) of the first communication scheme into a wireless signal of the first transmission signal corresponding to a first band in the transmission bands of the first communication scheme.

According to an embodiment, the electronic device may generate the first baseband transmission signal that includes a data packet of the first communication scheme and output the generated first baseband transmission signal to the transceiver (for example, the transceiver 631). The electronic device may use the transceiver to generate the first transmission signal by amplifying the first baseband transmission signal and to convert the amplified signal into a wireless signal.

In operation 1220, for example, the electronic device may convert the second baseband transmission signal (for example, PTx2_{—BB}) of the second communication scheme into a wireless signal of the second transmission signal corresponding to a second band in the transmission bands of the first communication scheme.

According to an embodiment, the electronic device may generate the second baseband transmission signal that includes a data packet of the second communication scheme and output the generated second baseband transmission signal to the transceiver. The electronic device may use the transceiver to generate the second transmission signal by amplifying the second baseband transmission signal through the transceiver and to convert the amplified signal into a wireless signal.

In operation 1230, for example, the electronic device may merge the converted first transmission signal and second transmission signal using the first merger (for example, the first merger 632).

FIG. 13 is a flowchart illustrating a wireless communication method of the electronic device according to an embodiment. The wireless communication method shown in FIG. 13 may illustrate the transmission signal amplifying method in operation 1120 of FIG. 11 and may include operations 1310 and 1320. The wireless communication method shown in FIG. 13 may be performed by at least one of the electronic device (for example, the electronic device 501) or the processor (for example, the processor 620) of the electronic device.

In operation 1310, for example, the electronic device may generate the first fixed voltage (for example, V_{cc1}) corresponding to the maximum output voltage of the first transmission signal (for example, PTx1) of the first communication scheme, which in turn corresponds to a first band in the transmission bands of the first communication scheme. The electronic device may further generate the second fixed voltage (for example, V_{cc2}) corresponding to the maximum output voltage of the second transmission signal (for example, PTx2) of the second communication scheme, which in turn corresponds to a second band in the transmission bands of the first communication scheme.

According to an embodiment, the electronic device may generate the first fixed voltage corresponding to the maximum output voltage of the first transmission signal. For example, the electronic device may generate a voltage higher than or equal to the maximum output voltage of the first transmission signal as the first fixed voltage.

According to an embodiment, the electronic device may generate the second fixed voltage corresponding to the maximum output voltage of the second transmission signal. For example, the electronic device may generate a voltage higher than or equal to the maximum output voltage of the second transmission signal as the second fixed voltage.

In operation 1320, for example, the electronic device may amplify the merged first transmission signal and second transmission signal through the PA (for example, the PA 633) operating on the basis of the generated first fixed voltage and second fixed voltage.

According to an embodiment, the electronic device may amplify the merged first transmission signal and second transmission signal through the PA operating on the basis of the first fixed voltage.

According to an embodiment, the electronic device may configure the generated first fixed voltage as the operation voltage of the PA. The electronic device may operate the PA by applying the first fixed voltage as the operation voltage to the PA. The electronic device may amplify the merged first and second transmission signals using the PA that is operating according to the configured first fixed voltage. According to an embodiment, the electronic device may also amplify the first transmission signal or the second transmission signal using the PA operating on the basis of the first fixed voltage.

According to an embodiment, the electronic device may configure the generated second fixed voltage as the operation voltage of the PA. The electronic device may operate the PA by applying the second fixed voltage as the operation voltage to the PA. The electronic device may amplify the merged first and second transmission signals using the PA that is operating according to the configured second fixed voltage. According to an embodiment, the electronic device may also amplify the first transmission signal or the second transmission signal using the PA operating on the basis of the second fixed voltage.

According to an embodiment, the electronic device may select the higher voltage from among the generated first fixed voltage and second fixed voltage and configure the selected fixed voltage as the operation voltage of the PA. The electronic device may operate the PA by applying the selected fixed voltage as the operation voltage. The electronic device may amplify the merged first and second transmission signals using the PA that is operating according to the selected fixed voltage. The electronic device may also amplify the first transmission signal or the second transmission signal using the PA that is operating according to the selected fixed voltage.

According to an embodiment, the electronic device may select the lower fixed voltage from among the generated first fixed voltage and second fixed voltage and configure the selected fixed voltage as the operation voltage of the PA. The electronic device may operate the PA by applying the selected fixed voltage as the operation voltage to the PA. The electronic device may amplify the merged first and second transmission signals using the PA that is operating according to the selected fixed voltage. The electronic device may also amplify the first transmission signal or the second transmission signal using the PA that is operating according to the selected fixed voltage.

FIG. 14 is a flowchart illustrating a wireless communication method of the electronic device according to an embodiment. The wireless communication method shown in FIG. 14 may illustrate the transmission signal amplifying method in operation 1120 of FIG. 11 and may include operations 1410 and 1420. The wireless communication method shown in FIG. 14 may be performed by at least one of the electronic device (for example, the electronic device 501) or the processor (for example, the processor 620) of the electronic device.

In operation 1410, for example, the electronic device may generate the first adaptive voltage (for example, V_{ad1}) corresponding to the output voltage of the first transmission signal (for example, PTx1) of the first communication scheme. The first adaptive voltage may be in the form of a stepwise signal and be generated based on a plurality of predetermined first threshold voltages. The electronic device may further generate the second adaptive voltage (for example, V_{ad2}) corresponding to the output voltage of the second transmission signal (for example, PTx2) of the second communication scheme. The second adaptive voltage may be in the form of a stepwise signal on be generated based on a plurality of predetermined second threshold voltages.

According to an embodiment, the electronic device may predetermine a plurality of first threshold voltages having a plurality of levels for the first transmission signal. The electronic device may generate the first adaptive voltage adaptively corresponding to the output voltage of the first transmission signal in the form of a stepwise signal on the basis of the plurality of predetermined first threshold voltages. The first adaptive voltage generated for the plurality of first threshold voltages may be stored in the memory (for example, the memory 130) of the electronic device as a table (for example, the first table).

According to an embodiment, the electronic device may predetermine a plurality of second threshold voltages having a plurality of levels for the second transmission signal. The electronic device may generate the second adaptive voltage adaptively corresponding to the output voltage of the second transmission signal in the form of a stepwise signal on the basis of the plurality of predetermined second threshold voltages. The second adaptive voltage generated for the plurality of second threshold voltages may be stored in the memory (for example, the memory 130) of the electronic device as a table (for example, the second table).

In operation 1420, for example, the electronic device may amplify the merged first transmission signal and second transmission signal using the PA (for example, the PA 633) that is operating on the basis of the generated first adaptive voltage. The electronic device may also amplify the merged first transmission signal and second transmission signal using the PA that is operating on the basis of the generated second adaptive voltage.

According to an embodiment, the electronic device may configure the generated first adaptive voltage as the operation voltage of the PA. The electronic device may operate the PA by applying the first adaptive voltage as the operation voltage to the PA. The electronic device may amplify the merged first transmission signal and second transmission signal using the PA that is operating according to the configured first adaptive voltage. The electronic device may also amplify the first transmission signal or the second transmission signal using the PA that is operating according to the configured first adaptive voltage.

According to an embodiment, the electronic device may configure the generated second adaptive voltage as the operation voltage of the PA. The electronic device may operate the PA by applying the second adaptive voltage as the operation voltage to the PA. The electronic device may amplify the merged first transmission signal and second transmission signal using the PA that is operating according to the configured second adaptive voltage. The electronic device may also amplify the first transmission signal or the second transmission signal using the PA that is operating according to the second adaptive voltage.

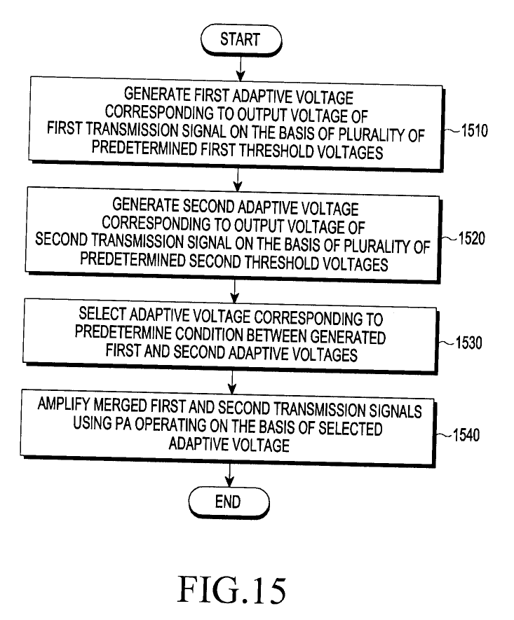

FIG. 15 is a flowchart illustrating a wireless communication method of the electronic device according to an embodiment. The wireless communication method shown in FIG. 15 may illustrate the transmission signal amplifying method in operation 1120 of FIG. 11 and may include operations 1510 to 1540. The wireless communication method shown in FIG. 15 may be performed by at least one of the electronic device (for example, the electronic device 501) or the processor (for example, the processor 620) of the electronic device.

In operation 1510, for example, the electronic device may generate the first adaptive voltage (for example, V_{ad1}) corresponding to the output voltage of the first transmission signal (for example, PTx1) of the first communication scheme. The first adaptive voltage may be in the form of a stepwise signal and be generated based on a plurality of predetermined first threshold voltages. Since operation 1510 is the same or similar to operation 1410 of FIG. 14, a detailed description thereof will be omitted.

In operation 1520, for example, the electronic device may generate the second adaptive voltage (for example, V_{ad2}) corresponding to the output voltage of the second transmission signal (for example, PTx2) of the second communication scheme. The second adaptive voltage may be in the form of a stepwise signal and be generated based on a plurality of predetermined second threshold voltages. Since operation 1520 is the same or similar to operation 1410 of FIG. 14, a detailed description thereof will be omitted.

In operation 1530, for example, the electronic device may select an adaptive voltage between the generated first adaptive voltage and second adaptive voltage, depending on a predetermined condition.

According to an embodiment, the electronic device may compare the first adaptive voltage and the second adaptive voltage. For example, the electronic device may compare a first table storing the first adaptive voltage and a second table storing the second adaptive voltage. The electronic device may select the adaptive voltage on the basis of the comparison result. According to an embodiment, the electronic device may compare all of the first table and the second table and select the lower adaptive voltage between the first adaptive voltage V_{ad1} and the second adaptive voltage V_{ad2}. According to an embodiment, the electronic device may compare the first table and the second table at various threshold voltages and select the higher adaptive voltage between the first adaptive voltage V_{ad1} and the second adaptive voltage V_{ad2} at each threshold voltage. According to an embodiment, the electronic device may compare the first table and the second table at various threshold voltages and select the lower adaptive voltage between the first adaptive voltage V_{ad1} and the second adaptive voltage V_{ad2} at each threshold voltage. According to an embodiment, the electronic device may compare the first table and the second table at various threshold voltages and select an adaptive voltage between the first adaptive voltage V_{ad1} and the second adaptive voltage V_{ad2} depending on different selection references for each threshold voltage. For example, the electronic device may select the higher adaptive voltage between the first adaptive voltage V_{ad1} and the second adaptive voltage V_{ad2} corresponding to the first threshold voltage and select the lower adaptive voltage between the first adaptive voltage V_{ad1} and the second adaptive voltage V_{ad2} corresponding to the second threshold voltage.

According to an embodiment, the plurality of first threshold voltages and the plurality of second threshold voltages may be configured to be the same as each other. According to an embodiment, the plurality of first threshold voltages and the plurality of second threshold voltages may be configured to be different from each other.

In operation 1540, for example, the electronic device may amplify the merged first transmission signal and second transmission signal using the PA (for example, the PA 633) that is operating on the basis of the selected adaptive voltage.

According to an embodiment, the electronic device may generate a third table corresponding to the selected adaptive voltage. The generated third table may be stored in the memory (for example, the memory 130) of the electronic device.

According to an embodiment, the electronic device may configure the selected adaptive voltage as the operation voltage of the PA. The electronic device may operate the PA by applying the selected adaptive voltage as the operation voltage to the PA. The electronic device may amplify the merged first transmission signal and second transmission signal using the PA that is operating according to the selected adaptive voltage. The electronic device may also amplify the first transmission signal or the second transmission signal using the PA that is operating according to the selected adaptive voltage.

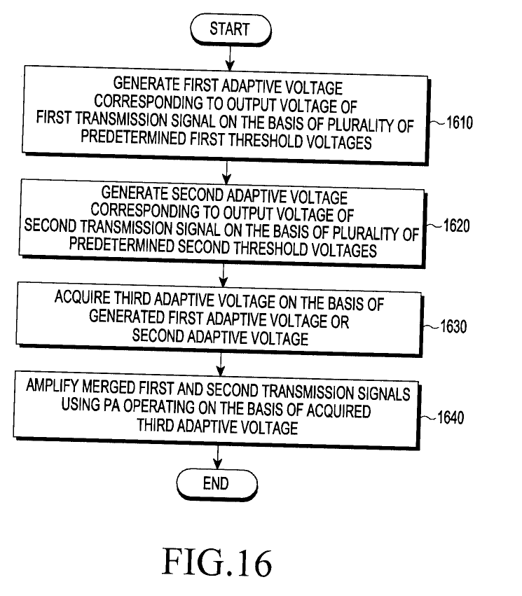

FIG. 16 is a flowchart illustrating a wireless communication method of the electronic device according to an embodiment. The wireless communication method shown in FIG. 16 may illustrate the transmission signal amplifying method in operation 1120 of FIG. 11 and may include operations 1610 to 1640. The wireless communication method shown in FIG. 16 may be performed by at least one of the electronic device (for example, the electronic device 501) or the processor (for example, the processor 620) of the electronic device.

In operation 1610, for example, the electronic device may generate the first adaptive voltage (for example, V_{ad1}) corresponding to the output voltage of the first transmission signal (for example, PTx1) of the first communication scheme. The first adaptive voltage may be in the form of a stepwise signal and be generated based on a plurality of predetermined first threshold voltages. Since operation 1610 is the same as operation 1510 of FIG. 15, a detailed description thereof will be omitted.

In operation 1620, for example, the electronic device may generate the second adaptive voltage (for example, V_{ad2}) corresponding to the output voltage of the second transmission signal (for example, PTx2) of the second communication scheme. The second adaptive voltage may be in the form of a stepwise signal and be generated based on a plurality of predetermined second threshold voltages. Since operation 1620 is the same as operation 1520 of FIG. 15, a detailed description thereof will be omitted.

In operation 1630, for example, the electronic device may acquire a third adaptive voltage at least on the basis of the generated first adaptive voltage and second adaptive voltage.

According to an embodiment, the electronic device may acquire intermediate values between the first adaptive voltage and the second adaptive voltage as the third adaptive voltage. For example, the electronic device may acquire the intermediate values between the first adaptive voltage V_{ad1} and the second adaptive voltage V_{ad}2 on the basis of the first table storing the first adaptive voltage and the second table storing the second adaptive voltage.

According to an embodiment, the electronic device may acquire, as the third adaptive voltage, voltages acquired by applying a predetermined weighted value to at least one of the generated first adaptive voltage V_{ad1} and second adaptive voltage V_{ad2} or according to a predetermined equation. For example, the weighted value or the equation may be predetermined by the user or preset to the electronic device. According to an embodiment, the equation may include various equations using at least one of the first adaptive voltage V_{ad1} and the second adaptive voltage V_{ad2}.

In operation 1640, for example, the electronic device may amplify the merged first transmission signal and second transmission signal using the PA (for example, the PA 633) that is operating on the basis of the acquired third adaptive voltage.

According to an embodiment, the electronic device may configure the acquired third adaptive voltage as the operation voltage of the PA. The electronic device may operate the PA by applying the acquired third adaptive voltage as the operation voltage to the PA. The electronic device may amplify the merged first transmission signal and second transmission signal using the PA that is operating according to the acquired third adaptive voltage. The electronic device may also amplify the first transmission signal or the second transmission signal using the PA that is operating according to the acquired third adaptive voltage.

FIG. 17 is a flowchart illustrating a wireless communication method of the electronic device according to an embodiment. The wireless communication method shown in FIG. 17 may illustrate the transmission signal amplifying method in operation 1120 of FIG. 11 and may include operations 1710 to 1730. The wireless communication method shown in FIG. 17 may be performed by at least one of the electronic device (for example, the electronic device 501) or 10 the processor (for example, the processor 620) of the electronic device.

In operation 1710, for example, the electronic device may merge the first baseband transmission signal (for example, PTx1_{—BB}) of the first communication scheme and the second baseband transmission signal (for example, PTx2_{—BB}) of the second communication scheme.

According to an embodiment, when the electronic device receives an input for transmitting first data of a first application (for example, a broadcast-related application or a data transmission/reception application) through the first communication scheme using the first band, the processor may generate the first baseband transmission signal corresponding to the first data.

According to an embodiment, when the electronic device receives an input for transmitting second data of a second application (for example, a message exchange application, a content exchange application, or a voice exchange application) through the second communication scheme using the second band, the processor may generate the second baseband transmission signal corresponding to the second data.

According to an embodiment, the electronic device may merge the first baseband transmission signal and the second baseband transmission signal using the second merger (for example, the second merger 637). According to an embodiment, the electronic device may generate the merged baseband transmission signal (for example, PTx_{—BB merge}) by summing the output voltage of the first baseband transmission signal and the output voltage of the second baseband transmission signal.

In operation 1720, the electronic device may generate the envelope voltage (for example, V_{E}) corresponding to the output voltage of the merged baseband transmission signal.

According to an embodiment, the electronic device may generate the envelope voltage such that the merged baseband transmission signal and the envelope voltage have a predetermined voltage width (for example, margin) therebetween.

In operation 1730, for example, the electronic device may amplify the merged first transmission signal and second transmission signal using the PA (for example, the PA 633) that is operating on the basis of the generated envelope voltage.

According to an embodiment, the electronic device may configure the generated envelope voltage as the operation voltage of the PA. The electronic device may control the PA to operate by applying the generated envelope voltage as the operation voltage to the PA. The electronic device may amplify the merged first and second transmission signals using the PA that is operating according to the generated envelope voltage. The electronic device may also amplify the first transmission signal or the second transmission signal using the PA that is operating according to the generated envelope voltage.

According to an embodiment, a wireless communication method of the electronic device (for example, the electronic device 501) may include an operation of merging the first transmission signal (for example, PTx1) of a first communication scheme corresponding to the first band that is one of transmission bands of the first communication scheme and a second transmission signal (for example, PTx2) of the second communication scheme corresponding to the second band that is one of the transmission bands, an operation of amplifying the merged first transmission signal and second transmission signal using a PA (for example, the PA 633), an operation of transmitting the amplified first transmission signal to a first external electronic device communicating in the first communication scheme, and an operation of transmitting the amplified second transmission signal to a second external electronic device communicating in the second communication scheme.

According to an embodiment, the operation of amplifying the merged first transmission signal and second transmission signal may include an operation of generating the first fixed voltage (for example, V_{cc1}) corresponding to a maximum output voltage of the first transmission signal or the second fixed voltage (for example, V_{cc2}) corresponding to a maximum output voltage of the second transmission signal and an operation of amplifying the merged first transmission signal and second transmission signal using the PA that is operating based on the generated first fixed voltage and second fixed voltage.

According to an embodiment, the operation of amplifying the merged first transmission signal and second transmission signal may include an operation of generating the first adaptive voltage (for example, V_{ad1}) corresponding to an output voltage of the first transmission signal, the first adaptive voltage being in the form of a stepwise signal and is generated based on a plurality of predetermined first threshold voltages and an operation of amplifying the merged first transmission signal and second transmission signal using the PA that is operating based on the generated first adaptive voltage.

According to an embodiment, the operation of amplifying the merged first transmission signal and second transmission signal may include an operation of generating the second adaptive voltage (for example, V_{ad2}) corresponding to an output voltage of the second transmission signal, the second adaptive voltage being in the form of a stepwise signal and is generated based on a plurality of predetermined second threshold voltages and an operation of amplifying the merged first transmission signal and second transmission signal using the PA that is operating based on the generated second adaptive voltage.

According to an embodiment, the operation of amplifying the merged first transmission signal and second transmission signal may include an operation of generating the first adaptive voltage (for example, V_{ad1}) corresponding to an output voltage of the first transmission signal, the first adaptive voltage being in the form of a stepwise signal and is generated based on a plurality of predetermined first threshold voltages, an operation of generating the second adaptive voltage (for example, V_{ad2}) corresponding to an output voltage of the second transmission signal, the second adaptive voltage being in the form of a stepwise signal and is generated based on a plurality of predetermined second threshold voltages, and an operation of amplifying the merged first transmission signal and second transmission signal using the PA that is operating based on the selected adaptive voltage.

According to an embodiment, the operation of amplifying the merged first transmission signal and second transmission signal may include an operation of generating the first adaptive voltage (for example, V_{ad1}) corresponding to an output voltage of the first transmission signal, the first adaptive voltage being in the form of a stepwise signal and is generated based on a plurality of predetermined first threshold voltages, an operation of generating the second adaptive voltage (for example, V_{ad2}) corresponding to an output voltage of the second transmission signal, the second adaptive voltage being in the form of a stepwise signal and is generated based on a plurality of predetermined second threshold voltages, an operation of acquiring a third adaptive voltage based on the first adaptive voltage and the second adaptive voltage, and an operation of amplifying the merged first transmission signal and second transmission signal using the PA that is operating based on the acquired third adaptive voltage.

According to an embodiment, the operation of amplifying the merged first transmission signal and second transmission signal may include an operation of merging the first baseband transmission signal (for example, PTx1_{—BB}) of the first communication scheme corresponding to the first transmission signal and the second baseband transmission signal (for example, PTx2_{—BB}) of the second communication scheme corresponding to the second transmission signal, an operation of generating an envelope voltage (for example, V_{E}) corresponding to an output voltage of the merged baseband transmission signal (for example, PTx1_{—BB}+PTx2_{—BB}=PTx1_{—BB}_{_}_{merge}), and an operation of amplifying the merged first transmission signal and second transmission signal using the PA that is operating based on the generated envelope voltage.

According to an embodiment, a computer-readable recording medium having a program recorded therein to be performed on a computer is provided. The program may include executable instructions that, when executed by a processor, cause the processor to perform operations through a communication circuit operationally connected to the processor. The operations may include an operation of merging the first transmission signal of the first communication scheme corresponding to the first band that is one of transmission bands of the first communication scheme and the second transmission signal of the second communication scheme corresponding to the second band that is one of the transmission bands through the communication circuit, an operation of amplifying the merged first transmission signal and second transmission signal using the PA, an operation of transmitting the amplified first transmission signal to a first external electronic device communicating in the first communication scheme, and an operation of transmitting the amplified second transmission signal to a second external electronic device communicating in the second communication scheme.

According to an embodiment, the operations may include an operation of generating the first fixed voltage corresponding to a maximum output voltage of the first transmission signal or the second fixed voltage corresponding to a maximum output voltage of the second transmission signal and an operation of amplifying the merged first transmission signal and second transmission signal using the PA that is operating based on the generated first fixed voltage or second fixed voltage.

According to an embodiment, the operations may include an operation of generating the first adaptive voltage adaptively corresponding to an output voltage of the first transmission signal, the first adaptive voltage being in the form of a stepwise signal and is generated based on a plurality of predetermined first threshold voltages and an operation of amplifying the merged first transmission signal and second transmission signal using the PA that is operating based on the generated first adaptive voltage.

According to an embodiment, the operations may include an operation of generating the second adaptive voltage adaptively corresponding to an output voltage of the first transmission signal, the second adaptive voltage being in the form of a stepwise signal and is generated based on a plurality of predetermined second threshold voltages and an operation of amplifying the merged first transmission signal and second transmission signal using the PA that is operating based on the generated second adaptive voltage.

According to an embodiment, the operations may include an operation of generating the first adaptive voltage adaptively corresponding to an output voltage of the first transmission signal, the first adaptive voltage being in the form of a stepwise signal and is generated based on a plurality of predetermined first threshold voltages, an operation of generating the second adaptive voltage adaptively corresponding to an output voltage of the second transmission signal, the second adaptive voltage being in the form of a stepwise signal and is generated based on a plurality of predetermined second threshold voltages, an operation of selecting an adaptive voltage between the first adaptive voltage and the second adaptive voltage based on a predetermined condition, and an operation of amplifying the merged first transmission signal and second transmission signal using the PA that is operating based on the selected adaptive voltage.

According to an embodiment, the operations may include an operation of generating the first adaptive voltage adaptively corresponding to an output voltage of the first transmission signal, the first adaptive voltage being in the form of a stepwise signal and is generated based on a plurality of predetermined first threshold voltages, an operation of generating the second adaptive voltage adaptively corresponding to an output voltage of the second transmission signal, the second adaptive voltage being in the form of a stepwise signal and is generated based on a plurality of predetermined second threshold voltages, an operation of acquiring a third adaptive voltage based on the first adaptive voltage or the second adaptive voltage, and an operation of amplifying the merged first transmission signal and second transmission signal using the PA that is operating based on the acquired third adaptive voltage.

According to an embodiment, the operations may include an operation of merging the first baseband transmission signal of the first communication scheme corresponding to the first transmission signal and the second baseband transmission signal of the second communication scheme corresponding to the second transmission signal, an operation of generating an envelope voltage corresponding to an output voltage of the merged baseband transmission signal, and an operation of amplifying the merged first transmission signal and second transmission signal using the PA that is operating based on the generated envelope voltage.

Certain aspects of the above-described embodiments of the present disclosure can be implemented in hardware, firmware or via the execution of software or computer code that can be stored in a recording medium such as a CD ROM, a Digital Versatile Disc (DVD), a magnetic tape, a RAM, a floppy disk, a hard disk, or a magneto-optical disk or computer code downloaded over a network originally stored on a remote recording medium or a non-transitory machine readable medium and to be stored on a local recording medium, so that the methods described herein can be rendered via such software that is stored on the recording medium using a general purpose computer, or a special processor or in programmable or dedicated hardware, such as an ASIC or FPGA. As would be understood in the art, the computer, the processor, microprocessor controller or the programmable hardware include memory components, e.g., RAM, ROM, Flash, etc. that may store or receive software or computer code that when accessed and executed by the computer, processor or hardware implement the processing methods described herein.

While the present disclosure has been shown and described with reference to various embodiments thereof, it will be understood by those skilled in the art that various changes in form and details may be made therein without departing from the present disclosure as defined by the appended claims and their equivalents.

What is claimed is:

1. An electronic device comprising:
a communication circuit; and
a processor operationally connected to the communication circuit, wherein the processor is configured to:
control the communication circuit to merge a first transmission signal of a first communication scheme corresponding to a first band that is one of transmission bands of the first communication scheme and a second transmission signal of a second communication scheme corresponding to a second band that is one of the transmission bands;
amplify the merged first transmission signal and second transmission signal using a power amplifier;
transmit the amplified first transmission signal to a first external electronic device communicating in the first communication scheme; and
transmit the amplified second transmission signal to a second external electronic device communicating in the second communication scheme.

2. The electronic device of claim 1, wherein the first communication scheme is a cellular communication network scheme, and the second communication scheme is a Device-to-Device (D2D) communication scheme based on cellular communication.

3. The electronic device of claim 1, wherein the communication circuit comprises:
a transceiver configured to convert a first baseband transmission signal of the first communication scheme corresponding to the first transmission signal and a second baseband transmission signal of the second communication scheme corresponding to the second transmission signal into the first transmission signal and the second transmission signal;
a first merger configured to merge the first transmission signal and second transmission signal; and
the power amplifier configured to amplify the merged first transmission signal and second transmission signal.

4. The electronic device of claim 3, wherein the communication circuit further comprises:
a first antenna configured to:
transmit the merged first transmission signal and second transmission signal,
receive a first reception signal of the first communication scheme corresponding to reception bands of the first communication scheme, and/or
receive a second reception signal of the second communication scheme corresponding to the second band of the first communication scheme;
a first duplexer configured to separate signals transmitted or received through the first antenna into a signal corresponding to the transmission bands of the first communication scheme and a signal corresponding to the reception bands of the first communication scheme; and
a switch configured to connect the power amplifier and the first duplexer to transmit the second transmission signal or to connect the transceiver and the first duplexer to receive the second reception signal.

5. The electronic device of claim 3, wherein the processor is further configured to:
generate a first fixed voltage corresponding to a maximum output voltage of the first transmission signal or a second fixed voltage corresponding to a maximum output voltage of the second transmission signal, and
amplify the merged first transmission signal and second transmission signal using the power amplifier that is operating based on the generated first fixed voltage or second fixed voltage.

6. The electronic device of claim 3, wherein the processor is further configured to:
generate a first adaptive voltage corresponding to an output voltage of the first transmission signal, the first adaptive voltage being in a form of a first stepwise signal and is generated based on a plurality of predetermined first threshold voltages;
generate a second adaptive voltage corresponding to an output voltage of the second transmission signal, the second adaptive voltage being in a form of a second stepwise signal and is generated based on a plurality of predetermined second threshold voltages;
select an adaptive voltage between the first adaptive voltage and the second adaptive voltage based on a predetermined condition; and
amplify the merged first transmission signal and second transmission signal using the power amplifier that is operating based on the selected adaptive voltage.

7. The electronic device of claim 3, wherein the processor is further configured to:
generate a first adaptive voltage corresponding to an output voltage of the first transmission signal, the first adaptive voltage being in a form of a first stepwise signal and is generated based on a plurality of predetermined first threshold voltages;
generate a second adaptive voltage corresponding to an output voltage of the second transmission signal, the second adaptive voltage being in a form of a second stepwise signal and is generated based on a plurality of predetermined second threshold voltages;
acquire a third adaptive voltage based on the first adaptive voltage or the second adaptive voltage; and
amplify the merged first transmission signal and second transmission signal using the power amplifier that is operating based on the acquired third adaptive voltage.

8. The electronic device of claim 3, wherein the communication circuit further comprises a second merger for merging the first baseband transmission signal and the second baseband transmission signal.

9. The electronic device of claim 8, wherein the processor is further configured to:
merge the first baseband transmission signal and the second baseband transmission signal;
generate an envelope voltage corresponding to an output voltage of the merged first baseband transmission signal and second baseband transmission signal; and
amplify the merged first transmission signal and second transmission signal using the power amplifier that is operating based on the generated envelope voltage.

10. The electronic device of claim 4, wherein the communication circuit further comprises:
a second antenna configured to receive a third reception signal of the first communication scheme corresponding to the reception bands of the first communication scheme or a fourth reception signal of the second communication scheme corresponding to the second band of the first communication scheme; and
a second duplexer configured to separate signals received through the second antenna into a signal corresponding to the second band and a signal corresponding to the reception bands.

11. A computer-readable recording medium having a program recorded therein to be performed on a computer, the program comprising executable instructions that, when executed by a processor, cause the processor to perform operations using a communication circuit operationally connected to the processor, the operations comprising:
merging a first transmission signal of a first communication scheme corresponding to a first band that is one of transmission bands of the first communication scheme and a second transmission signal of a second communication scheme corresponding to a second band that is one of the transmission bands;
amplifying the merged first transmission signal and second transmission signal using a power amplifier;
transmitting the amplified first transmission signal to a first external electronic device communicating in the first communication scheme; and
transmitting the amplified second transmission signal to a second external electronic device communicating in the second communication scheme.

12. The computer-readable recording medium of claim 11, wherein the operations further comprise:
generating a first fixed voltage corresponding to a maximum output voltage of the first transmission signal or a second fixed voltage corresponding to a maximum output voltage of the second transmission signal; and
amplifying the merged first transmission signal and second transmission signal using the power amplifier that is operating based on the generated first fixed voltage or second fixed voltage.

13. The computer-readable recording medium of claim 11, wherein the operations further comprise:
generating a first adaptive voltage corresponding to an output voltage of the first transmission signal, the first adaptive voltage being in a form of a first stepwise signal and is generated based on a plurality of predetermined first threshold voltages;
generating a second adaptive voltage corresponding to an output voltage of the second transmission signal, the second adaptive voltage being in a form of a second stepwise signal and is generated based on a plurality of predetermined second threshold voltages;
selecting an adaptive voltage between the first adaptive voltage and the second adaptive voltage based on a predetermined condition; and
amplifying the merged first transmission signal and second transmission signal using the power amplifier that is operating based on the selected adaptive voltage.

14. The computer-readable recording medium of claim 11, wherein the operations further comprise:
generating a first adaptive voltage corresponding to an output voltage of the first transmission signal, the first adaptive voltage being in a form of a first stepwise signal and is generated based on a plurality of predetermined first threshold voltages;
generating a second adaptive voltage corresponding to an output voltage of the second transmission signal, the second adaptive voltage being in a form of a second stepwise signal and is generated based on a plurality of predetermined second threshold voltages;
acquiring a third adaptive voltage based on the first adaptive voltage or the second adaptive voltage; and
amplifying the merged first transmission signal and second transmission signal using the power amplifier that is operating based on the acquired third adaptive voltage.

15. The computer-readable recording medium of claim 11, wherein the operations further comprise:
merging a first baseband transmission signal of the first communication scheme corresponding to the first transmission signal and a second baseband transmission signal of the second communication scheme corresponding to the second transmission signal;
generating an envelope voltage corresponding to an output voltage of the merged first baseband transmission signal and second baseband transmission signal; and
amplifying the merged first transmission signal and second transmission signal using the power amplifier that is operating based on the generated envelope voltage.

16. An electronic device comprising:
a housing;
an antenna unit at least partially disposed inside or on the housing;
at least one transceiver circuit comprising a first port, a second port, a third port, and a fourth port;
a first merger comprising a first input terminal electrically connected to the first port, a second input terminal electrically connected to the second port, and an output terminal;
a power amplifier comprising an input terminal electrically connected to the output terminal of the first merger and an output terminal; and
a switching unit comprising a first terminal electrically connected to the output terminal of the power amplifier, a second terminal electrically connected to the third port, and a third terminal electrically connected to the antenna unit,
wherein the fourth port is electrically connected to the antenna unit without being electrically connected to the first merger, the power amplifier, and the switching unit, and
wherein the transceiver circuit is configured to:
transmit Long-Term Evolution (LTE) UpLink (UL) transmission data corresponding to a first band that is one of LTE UL bands through the first port,
transmit LTE Device-to-Device (D2D) transmission data corresponding to a second band that is one of the LTE UL bands through the second port,
receive LTE D2D reception data corresponding to the second band through the third port, and
receive LTE DownLink (DL) reception data corresponding to LTE DL bands through the fourth port.

17. The electronic device of claim 16, further comprising a duplexer comprising a first terminal electrically connected to the antenna unit, a second terminal electrically connected to the third terminal of the switching unit, and a third terminal electrically connected to the fourth port,
wherein the duplexer is configured to separate data transmitted or received through the antenna unit into data corresponding to the LTE UL bands and data corresponding to the LTE DL bands.

18. The electronic device of claim 17, wherein the duplexer separates the data using a time division duplex scheme.

19. The electronic device of claim 17, wherein the switching unit is configured to:
switch to the first terminal of the switching unit to connect the power amplifier and the duplexer when the LTE UL transmission data, the LTE D2D transmission data, or the LTE UL transmission data and the LTE D2D transmission data, which are merged through the first merger, is transmitted; and
switch to the second terminal of the switching unit to connect the transceiver and the duplexer when the LTE D2D reception data is received.

20. The electronic device of claim 16, further comprising:
at least one processor configured to control the antenna unit, the transceiver circuit, the first merger, the power amplifier, and the switching unit;
a second merger comprising a first input terminal electrically connected to the processor, a second input terminal electrically connected to the processor, and an output terminal; and
a power controller configured to control an operation of the power amplifier based on an envelope voltage,
wherein the envelope voltage corresponds to an output voltage of baseband transmission data obtained by using the second merger to merge LTE UL baseband transmission data corresponding to the LTE UL transmission data and LTE D2D baseband transmission data corresponding to the LTE D2D transmission data.
